(19) United States
(12) Patent Application Publication
(10) Pub. No.: US 2025/0167125 A1
(43) Pub. Date: May 22, 2025

(54) BUILD-UP FILM AND PRE-PREG SUBSTRATES IN ISOLATION PACKAGES

(71) Applicant: TEXAS INSTRUMENTS INCORPORATED, Dallas, TX (US)

(72) Inventors: Sylvester ANKAMAH-KUSI, McKinney, TX (US); Guangxu LI, Allen, TX (US); Rajen Manicon MURUGAN, Dallas, TX (US); Usman CHAUDHRY, McKinney, TX (US)

(21) Appl. No.: 18/920,738

(22) Filed: Oct. 18, 2024

Related U.S. Application Data
(60) Provisional application No. 63/601,702, filed on Nov. 21, 2023.

(51) Int. Cl. H01L 23/538; H01L 21/48; H01L 23/00; H01L 23/14; H01L 23/31; H01L 25/00; H01L 25/065

(52) U.S. Cl. CPC H01L 23/5386; H01L 21/4857; H01L 23/5383; H01L 25/0655; H10D 1/20; H01L 23/145; H01L 23/3107; H01L 24/16; H01L 25/50; H01L 2224/16227

(57) ABSTRACT

In examples, a semiconductor package includes a substrate including a build-up film isolation layer and first and second pre-preg layers contacting opposing lateral sides of the build-up film isolation layer, the first pre-preg layer including a first metallization, and the second pre-preg layer including a second metallization not in physical contact with the first metallization. The package also includes solder mask layers on top and bottom surfaces of the substrate, a first semiconductor die coupled to the first metallization, and a second semiconductor die coupled to the second metallization, the first and second semiconductor dies configured to operate in separate voltage domains. The package also includes a mold compound covering the substrate and the first and second semiconductor dies.

### CROSS-REFERENCE TO RELATED APPLICATIONS

The present application claims priority to U.S. Provisional Patent Application No. 63/601,702, which was filed Nov. 21, 2023, is titled “HYBRID ABF-PREPREG ISO-ETS,” and is hereby incorporated herein by reference in its entirety.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such circuits on a wafer is called fabrication. After wafer fabrication, the wafer is cut into multiple pieces, called semiconductor dies, with each die containing one of the circuits. The cutting, or sawing, of the wafer into individual dies is called singulation. An individual die may then be coupled to a substrate or die pad. The resulting structure is subsequently covered with a mold compound to produce a package.

### SUMMARY

In examples, a semiconductor package includes a substrate including a build-up film isolation layer and first and second pre-preg layers contacting opposing lateral sides of the build-up film isolation layer, the first pre-preg layer including a first metallization, and the second pre-preg layer including a second metallization not in physical contact with the first metallization. The package also includes solder mask layers on top and bottom surfaces of the substrate, a first semiconductor die coupled to the first metallization, and a second semiconductor die coupled to the second metallization, the first and second semiconductor dies configured to operate in separate voltage domains. The package also includes a mold compound covering the substrate and the first and second semiconductor dies.

In examples, a method for manufacturing a semiconductor package includes forming two or more layers of a substrate by iteratively plating a metal layer, applying a build-up film to the metal layer using a first mask, applying a first pre-preg to the metal layer on a first lateral side of the build-up film, and applying a second pre-preg to the metal layer on a second lateral side of the build-up film, the second lateral side opposing the first lateral side. The method includes applying a solder mask layer to the substrate, coupling first and second semiconductor dies to the substrate, the first and second semiconductor dies configured to operate in separate voltage domains, and covering the substrate and the first and second semiconductor dies with a mold compound.

### BRIEF DESCRIPTION OF THE DRAWINGS

FIG. 1A is a cross-sectional view of a semiconductor package having a build-up film (BUF) and pre-preg substrate, in accordance with various examples.

FIG. 1B is a top-down view of a semiconductor package having a BUF and pre-preg substrate, in accordance with various examples.

FIG. 1C is a perspective view of a semiconductor package having a BUF and pre-preg substrate, in accordance with various examples.

FIG. 2 is a flow diagram of a method for manufacturing a semiconductor package having a BUF and pre-preg substrate, in accordance with various examples.

FIG. 3A depicts a step in a process flow for manufacturing a semiconductor package having a BUF and pre-preg substrate, in accordance with various examples.

FIG. 3B depicts a step in a process flow for manufacturing a semiconductor package having a BUF and pre-preg substrate, in accordance with various examples.

FIG. 4A depicts a step in a process flow for manufacturing a semiconductor package having a BUF and pre-preg substrate, in accordance with various examples.

FIG. 4B depicts a step in a process flow for manufacturing a semiconductor package having a BUF and pre-preg substrate, in accordance with various examples.

FIG. 5A depicts a step in a process flow for manufacturing a semiconductor package having a BUF and pre-preg substrate, in accordance with various examples.

FIG. 5B depicts a step in a process flow for manufacturing a semiconductor package having a BUF and pre-preg substrate, in accordance with various examples.

FIG. 6A depicts a step in a process flow for manufacturing a semiconductor package having a BUF and pre-preg substrate, in accordance with various examples.

FIG. 6B depicts a step in a process flow for manufacturing a semiconductor package having a BUF and pre-preg substrate, in accordance with various examples.

FIG. 7A depicts a step in a process flow for manufacturing a semiconductor package having a BUF and pre-preg substrate, in accordance with various examples.

FIG. 7B depicts a step in a process flow for manufacturing a semiconductor package having a BUF and pre-preg substrate, in accordance with various examples.

FIG. 8A depicts a step in a process flow for manufacturing a semiconductor package having a BUF and pre-preg substrate, in accordance with various examples.

FIG. 8B depicts a step in a process flow for manufacturing a semiconductor package having a BUF and pre-preg substrate, in accordance with various examples.

FIG. 9A depicts a step in a process flow for manufacturing a semiconductor package having a BUF and pre-preg substrate, in accordance with various examples.

FIG. 9B depicts a step in a process flow for manufacturing a semiconductor package having a BUF and pre-preg substrate, in accordance with various examples.

FIG. 10A depicts a step in a process flow for manufacturing a semiconductor package having a BUF and pre-preg substrate, in accordance with various examples.

FIG. 10B depicts a step in a process flow for manufacturing a semiconductor package having a BUF and pre-preg substrate, in accordance with various examples.

FIG. 11A depicts a step in a process flow for manufacturing a semiconductor package having a BUF and pre-preg substrate, in accordance with various examples.

FIG. 11B depicts a step in a process flow for manufacturing a semiconductor package having a BUF and pre-preg substrate, in accordance with various examples.

FIG. 12A depicts a step in a process flow for manufacturing a semiconductor package having a BUF and pre-preg substrate, in accordance with various examples.

FIG. 12B depicts a step in a process flow for manufacturing a semiconductor package having a BUF and pre-preg substrate, in accordance with various examples.

FIG. 13A depicts a step in a process flow for manufacturing a semiconductor package having a BUF and pre-preg substrate, in accordance with various examples.

FIG. 13B depicts a step in a process flow for manufacturing a semiconductor package having a BUF and pre-preg substrate, in accordance with various examples.

FIG. 14A depicts a step in a process flow for manufacturing a semiconductor package having a BUF and pre-preg substrate, in accordance with various examples.

FIG. 14B depicts a step in a process flow for manufacturing a semiconductor package having a BUF and pre-preg substrate, in accordance with various examples.

FIG. 15A depicts a step in a process flow for manufacturing a semiconductor package having a BUF and pre-preg substrate, in accordance with various examples.

FIG. 15B depicts a step in a process flow for manufacturing a semiconductor package having a BUF and pre-preg substrate, in accordance with various examples.

FIG. 16A depicts a step in a process flow for manufacturing a semiconductor package having a BUF and pre-preg substrate, in accordance with various examples.

FIG. 16B depicts a step in a process flow for manufacturing a semiconductor package having a BUF and pre-preg substrate, in accordance with various examples.

FIG. 17A depicts a step in a process flow for manufacturing a semiconductor package having a BUF and pre-preg substrate, in accordance with various examples.

FIG. 17B depicts a step in a process flow for manufacturing a semiconductor package having a BUF and pre-preg substrate, in accordance with various examples.

FIG. 18A depicts a step in a process flow for manufacturing a semiconductor package having a BUF and pre-preg substrate, in accordance with various examples.

FIG. 18B depicts a step in a process flow for manufacturing a semiconductor package having a BUF and pre-preg substrate, in accordance with various examples.

FIG. 19A depicts a step in a process flow for manufacturing a semiconductor package having a BUF and pre-preg substrate, in accordance with various examples.

FIG. 19B depicts a step in a process flow for manufacturing a semiconductor package having a BUF and pre-preg substrate, in accordance with various examples.

FIG. 20A depicts a step in a process flow for manufacturing a semiconductor package having a BUF and pre-preg substrate, in accordance with various examples.

FIG. 20B depicts a step in a process flow for manufacturing a semiconductor package having a BUF and pre-preg substrate, in accordance with various examples.

FIG. 21A depicts a step in a process flow for manufacturing a semiconductor package having a BUF and pre-preg substrate, in accordance with various examples.

FIG. 21B depicts a step in a process flow for manufacturing a semiconductor package having a BUF and pre-preg substrate, in accordance with various examples.

FIG. 22A depicts a step in a process flow for manufacturing a semiconductor package having a BUF and pre-preg substrate, in accordance with various examples.

FIG. 22B depicts a step in a process flow for manufacturing a semiconductor package having a BUF and pre-preg substrate, in accordance with various examples.

FIG. 23A depicts a step in a process flow for manufacturing a semiconductor package having a BUF and pre-preg substrate, in accordance with various examples.

FIG. 23B depicts a step in a process flow for manufacturing a semiconductor package having a BUF and pre-preg substrate, in accordance with various examples.

FIG. 24A depicts a step in a process flow for manufacturing a semiconductor package having a BUF and pre-preg substrate, in accordance with various examples.

FIG. 24B depicts a step in a process flow for manufacturing a semiconductor package having a BUF and pre-preg substrate, in accordance with various examples.

FIG. 25A depicts a step in a process flow for manufacturing a semiconductor package having a BUF and pre-preg substrate, in accordance with various examples.

FIG. 25B depicts a step in a process flow for manufacturing a semiconductor package having a BUF and pre-preg substrate, in accordance with various examples.

FIG. 26A depicts a step in a process flow for manufacturing a semiconductor package having a BUF and pre-preg substrate, in accordance with various examples.

FIG. 26B depicts a step in a process flow for manufacturing a semiconductor package having a BUF and pre-preg substrate, in accordance with various examples.

FIG. 27A depicts a step in a process flow for manufacturing a semiconductor package having a BUF and pre-preg substrate, in accordance with various examples.

FIG. 27B depicts a step in a process flow for manufacturing a semiconductor package having a BUF and pre-preg substrate, in accordance with various examples.

FIG. 28A depicts a step in a process flow for manufacturing a semiconductor package having a BUF and pre-preg substrate, in accordance with various examples.

FIG. 28B depicts a step in a process flow for manufacturing a semiconductor package having a BUF and pre-preg substrate, in accordance with various examples.

FIG. 29A depicts a step in a process flow for manufacturing a semiconductor package having a BUF and pre-preg substrate, in accordance with various examples.

FIG. 29B depicts a step in a process flow for manufacturing a semiconductor package having a BUF and pre-preg substrate, in accordance with various examples.

FIG. 30A depicts a step in a process flow for manufacturing a semiconductor package having a BUF and pre-preg substrate, in accordance with various examples.

FIG. 30B depicts a step in a process flow for manufacturing a semiconductor package having a BUF and pre-preg substrate, in accordance with various examples.

FIG. 31A depicts a step in a process flow for manufacturing a semiconductor package having a BUF and pre-preg substrate, in accordance with various examples.

FIG. 31B depicts a step in a process flow for manufacturing a semiconductor package having a BUF and pre-preg substrate, in accordance with various examples.

FIG. 32A depicts a step in a process flow for manufacturing a semiconductor package having a BUF and pre-preg substrate, in accordance with various examples.

FIG. 32B depicts a step in a process flow for manufacturing a semiconductor package having a BUF and pre-preg substrate, in accordance with various examples.

FIG. 33A depicts a step in a process flow for manufacturing a semiconductor package having a BUF and pre-preg substrate, in accordance with various examples.

FIG. 33B depicts a step in a process flow for manufacturing a semiconductor package having a BUF and pre-preg substrate, in accordance with various examples.

FIG. 34A depicts a step in a process flow for manufacturing a semiconductor package having a BUF and pre-preg substrate, in accordance with various examples.

FIG. 34B depicts a step in a process flow for manufacturing a semiconductor package having a BUF and pre-preg substrate, in accordance with various examples.

FIG. 35A depicts a step in a process flow for manufacturing a semiconductor package having a BUF and pre-preg substrate, in accordance with various examples.

FIG. 35B depicts a step in a process flow for manufacturing a semiconductor package having a BUF and pre-preg substrate, in accordance with various examples.

FIG. 36A depicts a step in a process flow for manufacturing a semiconductor package having a BUF and pre-preg substrate, in accordance with various examples.

FIG. 36B depicts a step in a process flow for manufacturing a semiconductor package having a BUF and pre-preg substrate, in accordance with various examples.

FIG. 37A depicts a step in a process flow for manufacturing a semiconductor package having a BUF and pre-preg substrate, in accordance with various examples.

FIG. 37B depicts a step in a process flow for manufacturing a semiconductor package having a BUF and pre-preg substrate, in accordance with various examples.

FIG. 38A depicts a step in a process flow for manufacturing a semiconductor package having a BUF and pre-preg substrate, in accordance with various examples.

FIG. 38B depicts a step in a process flow for manufacturing a semiconductor package having a BUF and pre-preg substrate, in accordance with various examples.

FIG. 39A depicts a step in a process flow for manufacturing a semiconductor package having a BUF and pre-preg substrate, in accordance with various examples.

FIG. 39B depicts a step in a process flow for manufacturing a semiconductor package having a BUF and pre-preg substrate, in accordance with various examples.

FIG. 40A depicts a step in a process flow for manufacturing a semiconductor package having a BUF and pre-preg substrate, in accordance with various examples.

FIG. 40B depicts a step in a process flow for manufacturing a semiconductor package having a BUF and pre-preg substrate, in accordance with various examples.

FIG. 41 is a block diagram of an electronic device including a semiconductor package having a BUF and pre-preg substrate, in accordance with various examples.

### DETAILED DESCRIPTION

A technical challenge with semiconductor package substrates that include build-up films (BUFs), such as Ajinomoto Build-up Film (ABF), is the risk of mechanical failure, particularly cracking and delamination of the BUF layer. This is a critical issue for isolation devices built with substrates in which the BUF serves as the dielectric material. The BUF layer is vulnerable to mechanical stress, especially during thermal cycling or high-strain conditions typical in semiconductor packaging processes. Over time, these stresses can cause the BUF to crack or separate from the underlying layers, leading to delamination. This jeopardizes the mechanical integrity of the package, creating package reliability concerns. In these cases, any crack or delamination in the dielectric layer compromises the isolation and structural strength of the package, ultimately affecting the overall performance and durability of the device.

In contrast, pre-preg materials (pre-impregnated composite fibers) used in package substrates (e.g., in embedded trace substrates (ETS)) present a different set of problems. While pre-preg is widely used as an insulating and bonding material, the isolation properties of the pre-preg are not sufficient for certain applications, particularly in high-voltage or high-frequency devices. Pre-preg lacks the dielectric performance necessary to provide adequate isolation between conductive layers or traces within the package substrate. This is because the fiberglass weave of the pre-preg transports charges effectively. As a result, devices that rely on pre-preg for isolation may suffer from electrical breakdown or leakage, undermining the ability of the device to function in high-stress environments. Therefore, the use of pre-preg in these substrates requires additional design considerations or complementary materials to meet isolation standards, making it less ideal for applications where robust electrical isolation is critical.

This description presents various examples of a semiconductor package that mitigates the technical challenges described above by including a package substrate that combines build-up film and pre-preg layers. Specifically, the build-up film layer is positioned in an isolation region between the metallization for two distinct voltage domains. For example, the isolation region may include a pair of physically separate coils that are covered by the build-up film layer. The remainder of the substrate, including the metallizations for the two distinct voltage domains, are covered by the pre-preg layers. The build-up film layer provides superior isolation characteristics in the isolation region, where such characteristics are useful, because the build-up film layer contains non-charge-transporting polymeric particles instead of the charge-transporting fiberglass weave of pre-preg. Further, the pre-preg layers provide superior mechanical stability in the non-isolation regions of the substrate, where such stability is useful. In this way, the relative strengths of build-up films and pre-preg are leveraged while the drawbacks of buildup-up films and pre-preg are minimized. In some examples, semiconductor packages include a substrate including first metallization, second metallization, a first coil, and a second coil. The first metallization and the first coil are in a first voltage domain and the second metallization and the second coil are in a second voltage domain. The first metallization is covered by a first pre-preg layer, and the second metallization is covered by a second pre-preg layer. The first and second coils are covered by a build-up film isolation layer. The example package also includes a first solder mask layer contacting top surfaces of the first and second pre-preg layers and of the build-up film isolation layer, and a second solder mask layer contacting bottom surfaces of the first and second pre-preg layers and of the build-up film isolation layer. The example package further includes a first semiconductor die coupled to the first metallization and the first coil, a second semiconductor die coupled to the second metallization and the second coil, and a mold compound contacting the first and second semiconductor dies and the first solder mask.

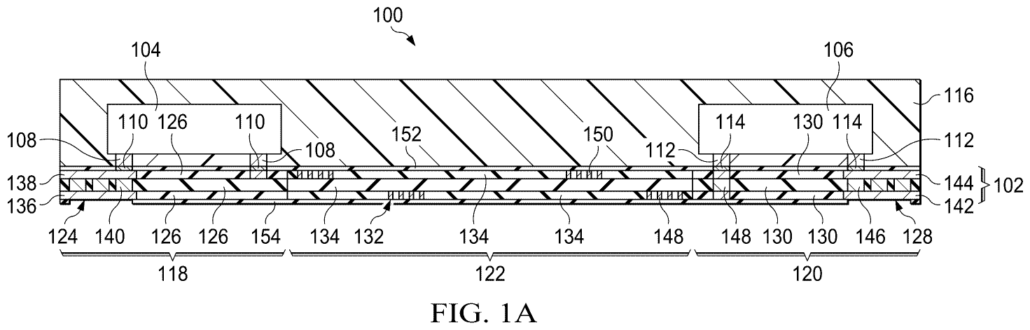

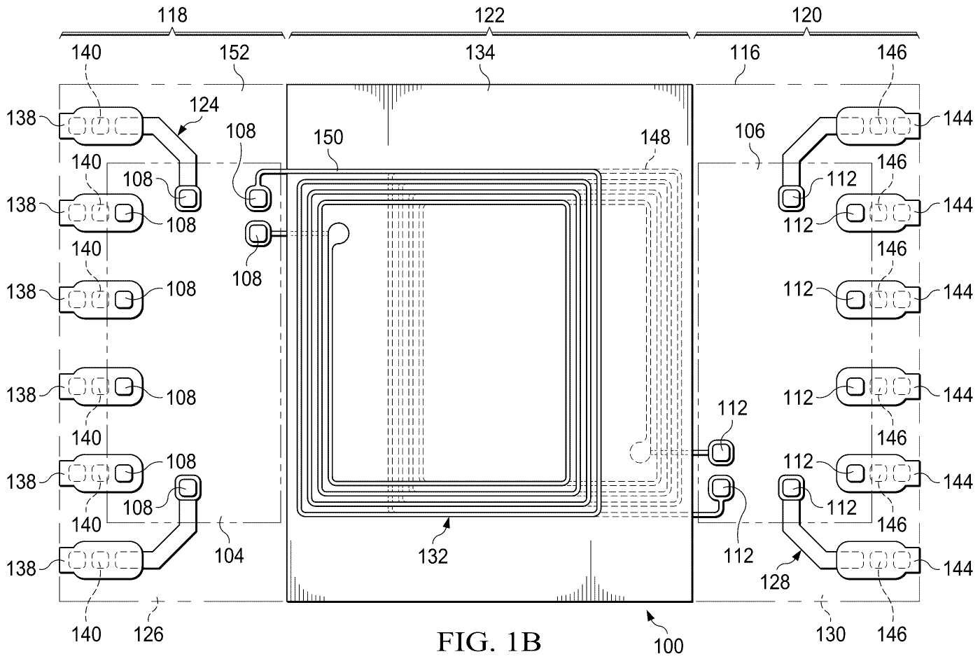

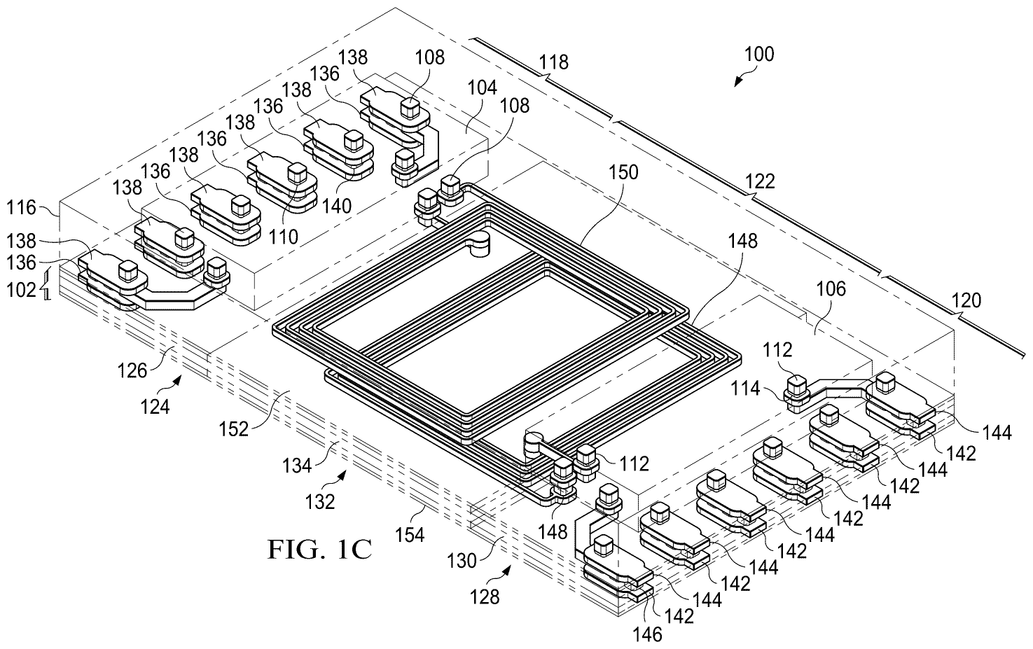

FIG. 1A is a cross-sectional view of a semiconductor package 100 having a build-up film (BUF) and pre-preg substrate, in accordance with various examples. FIG. 1B is a top-down view of the semiconductor package 100 having a BUF and pre-preg substrate, in accordance with various examples. FIG. 1C is a perspective view of the semiconductor package 100 having a BUF and pre-preg substrate, in accordance with various examples. FIGS. 1A-1C are described in parallel. The example semiconductor package 100 includes a substrate 102, a semiconductor die 104, and a semiconductor die 106. The semiconductor die 104 may be coupled to the substrate 102 by pillars 108 (e.g., copper pillars) and solder members 110. The semiconductor die 106 may be coupled to the substrate 102 by pillars 112 (e.g., copper pillars) and solder members 114. A mold compound 116 covers the semiconductor dies 104, 106, the pillars 108, 112, and the various structures within the substrate 102. In examples, the semiconductor dies 104, 106 are configured to operate in separate voltage domains. Accordingly, the semiconductor package 100 may be referred to as an isolation package or isolation device.

Because the semiconductor package 100 is an isolation device, the substrate 102, which facilitates such isolation between separate voltage domains, may be referred to as an isolation substrate. In examples, the substrate 102 includes a pre-preg layer 118, a pre-preg layer 120, and a build-up film (BUF) isolation layer 122 in between the pre-preg layer 118 and the pre-preg layer 120. The pre-preg layer 118 may physically contact a lateral surface of the BUF isolation layer 122, and the pre-preg layer 120 may physically contact a different lateral surface of the BUF isolation layer 122 opposite the surface contacting the pre-preg layer 118. The pre-preg layer 118 may include a metallization 124 and a pre-preg material 126. The pre-preg layer 120 may include a metallization 128 and a pre-preg material 130. The BUF isolation layer 122 may include a metallization 132 and a build-up film (BUF) 134.

In examples, the metallization 124 includes a metal layer 136, a metal layer 138, and vias 140 extending between and coupling the metal layers 136 and 138. In examples, one or more of the metal layers 136, 138 and the vias 140 includes copper. In examples, one or more of the metal layers 136, 138 and the vias 140 is optionally plated with a suitable metal or alloy, such as nickel, gold, tin, and/or palladium. The metallization 128 may include a metal layer 142, a metal layer 144, and vias 146 extending between and coupling the metal layers 142 and 144. In examples, one or more of the metal layers 142, 144 and the vias 146 includes copper. In examples, one or more of the metal layers 142, 144 and the vias 146 is optionally plated with a suitable metal or alloy, such as nickel, gold, tin, and/or palladium.

In examples, the metallization 132 includes a coil 148 and a coil 150. The coils 148, 150 are physically separate from each other, meaning that the coils 148, 150 do not physically contact each other. The coils 148, 150 may comprise copper or another suitable metal or alloy, and may be optionally plated with a suitable metal or alloy, such as nickel, gold, tin, and/or palladium. Although two coils 148, 150 are shown in FIG. 1A, in some examples, three or more coils may be included. For example, a pair of coils may be coupled to each other by one or more vias, and a third coil may be co-located within the BUF isolation layer 122 with the pair of coils but may be physically separate from the pair of coils.

The pre-preg materials 126, 130 may be any suitable type of pre-preg that is useful to achieve the specific operational objectives described herein. Pre-preg materials are useful for their adhesive, dielectric, and mechanical properties. They have a low dielectric constant (Dk) and low loss tangent (Df). Pre-preg provides adhesive strength for bonding between conductive layers, reducing the likelihood of delamination under mechanical or thermal stress. Pre-preg materials also have substantial mechanical strength due to their fiberglass reinforcement, enabling them to withstand bending, warping, and other stresses during manufacturing and use. Pre-preg materials' thermal stability is supported by a high glass transition temperature (Tg) and a low coefficient of thermal expansion (CTE), which help maintain structural integrity during thermal cycling. Additionally, pre-preg materials offer moisture resistance, which helps preserve electrical insulation in humid conditions. Furthermore, pre-preg thickness can be precisely controlled during lamination, allowing for tight tolerances in multilayer semiconductor packages. The pre-preg materials 126, 130 may comprise a variety of materials, including resin and fiberglass, which may individually or synergistically provide the various benefits of pre-preg materials described herein. The composition of the pre-preg materials 126, 130 is 36%-77% fiberglass by weight, with excursions outside of this range being disadvantageous because mechanical and electrical performance will be significantly and negatively impacted.

The BUF 134 may be any suitable build-up film, such as AJINOMOTO® build-up film (ABF). The BUF 134 has properties that contribute to its electrical isolation capabilities. For example, the BUF 134 has a relatively low dielectric constant (Dk), which reduces signal delay and cross-talk between circuit traces, helping to maintain signal integrity. The dielectric constant of the BUF 134 is between 3.2 and 3.4 at 5.8 GHz, with excursions outside of this range being disadvantageous because mechanical and electrical performance will be significantly and negatively impacted. The BUF 134 also has a relatively low dissipation factor (Df), which minimizes energy loss as heat, thereby reducing signal attenuation. The thermal stability of the BUF 134 enables it to endure the heat generated during operation and manufacturing processes, preserving the electrical properties of the BUF 134 over time. The BUF 134 has a coefficient of thermal expansion (CTE) ranging from 20 parts per million per degree Kelvin (ppm/K) to 39 ppm/K, with excursions outside of this range being disadvantageous because mechanical and electrical performance will be significantly and negatively impacted. Additionally, the high insulation resistance of the BUF 134 prevents leakage currents, maintaining separation between conductive layers. The BUF 134 also resists moisture absorption, which helps in maintaining consistent electrical performance in different environmental conditions. The BUF 134 may include an epoxy-based resin, an inorganic filler, and a curing agent. In examples, the BUF 134 does not include fiberglass, as the specific combination of fiberglass and epoxy in the pre-preg materials 126, 130 provide the pre-preg materials 126, 130 with superior mechanical properties but also with poor isolation capabilities, and because in the case of the BUF 134, superior isolation capabilities (relative to the pre-preg materials 126, 130) are critical.

To achieve adequate isolation, the minimum lateral distance between the third metallization 132 in the BUF isolation layer 122 and an interface between the BUF isolation layer 122 with the closest pre-preg layer 118, 120 is at least 100 microns. A lateral distance below this range results in unacceptably poor isolation.

One or more of the pillars 108 may be coupled to the metal layer 138 by solder members 110. Similarly, one or more of the pillars 108 may be coupled to the coil 150 by a solder member 110. One or more of the pillars 112 may be coupled to the metal layer 144 by solder members 114. Similarly, one or more of the pillars 112 may be coupled to the coil 148 by a solder member 114.

A solder mask layer 152 may cover at least some of the top surface of the substrate 102, e.g., top surfaces of the pre-preg layers 118, 120 and of the BUF isolation layer 122. Similarly, a solder mask layer 154 may cover at least some of the bottom surface of the substrate 102, e.g., bottom surfaces of the pre-preg layers 118, 120 and of the BUF isolation layer 122. The solder mask layers 152, 154 may provide insulative and protective (e.g., from solder and debris) properties that benefit the substrate 102.

The substrate 102 may be an embedded trace substrate (ETS). An ETS is a multi-layered structure in which the copper traces are embedded within the insulating layers of the substrate, rather than being patterned on the surface. In such examples, the copper traces are buried between layers of insulating material, such as epoxy resins or build-up films, during the fabrication process. The substrate includes alternating layers of conductive traces and dielectric materials, which are laminated together. The embedding of traces allows for precise control over the thickness and placement of the wiring, and the entire structure supports fine pitch connections, enabling dense interconnect routing between different components of the semiconductor device. Through-hole vias or laser-drilled microvias connect the embedded traces to the outer layers of the substrate, facilitating electrical connections to other components, such as integrated circuits or solder bumps.

In operation, the semiconductor dies 104, 106 operate in separate voltage domains. Because the semiconductor die 104 is coupled to the metallization 124 in the pre-preg layer 118, the pre-preg layer 118 and the metallization 124 belong to and operate in the same voltage domain as the semiconductor die 104. Because the semiconductor die 106 is coupled to the metallization 128 in the pre-preg layer 120, the pre-preg layer 120 and the metallization 128 belong to and operate in the same voltage domain as the semiconductor die 106. Further, the coil 150 is coupled to the semiconductor die 104, so the coil 150 operates in the same voltage domain as the semiconductor die 104. Similarly, the coil 148 is coupled to the semiconductor die 106, so the coil 148 operates in the same voltage domain as the semiconductor die 106. The separate voltage domains may interact with each other through the electromagnetic coupling of the coils 148, 150. The BUF 134 provides adequate isolation to the metallization 132 (e.g., the coils 148, 150), while the remainder of the substrate 102 includes pre-preg (e.g., pre-preg 126, 130), which provides mechanical stability and mitigates the risks described above, such as delamination, cracking, etc.

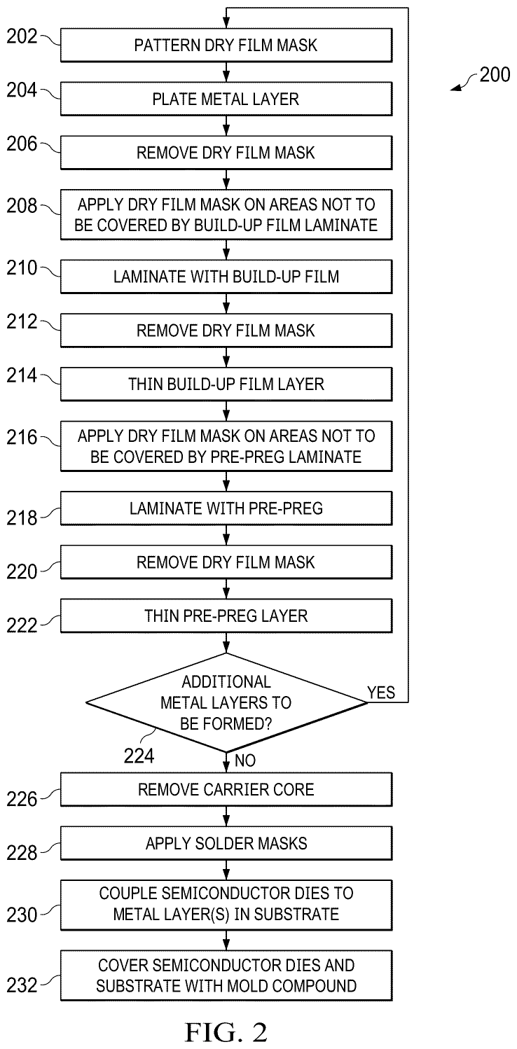

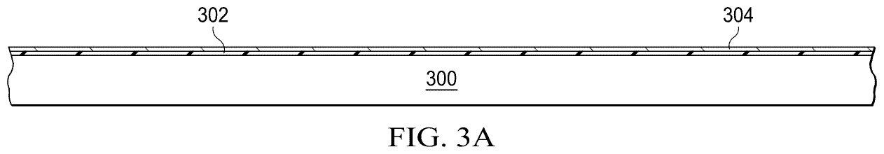

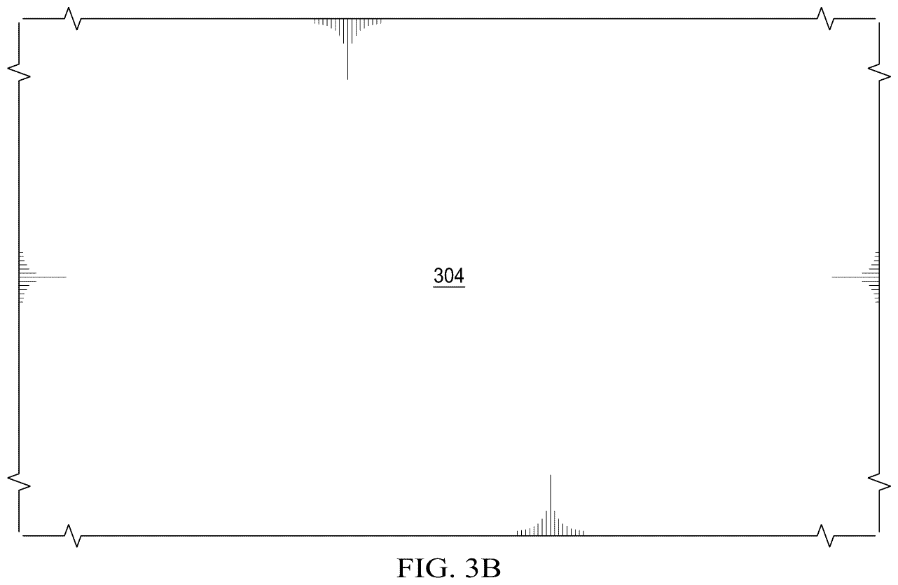

FIG. 2 is a flow diagram of a method 200 for manufacturing a semiconductor package having a BUF and pre-preg substrate (e.g., the semiconductor package 100), in accordance with various examples. FIGS. 3A-40B are a process flow for manufacturing a semiconductor package having a BUF and pre-preg substrate (e.g., the semiconductor package 100), in accordance with various examples.

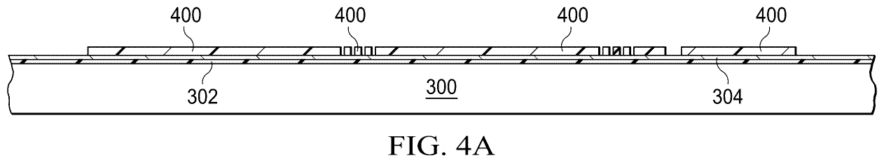

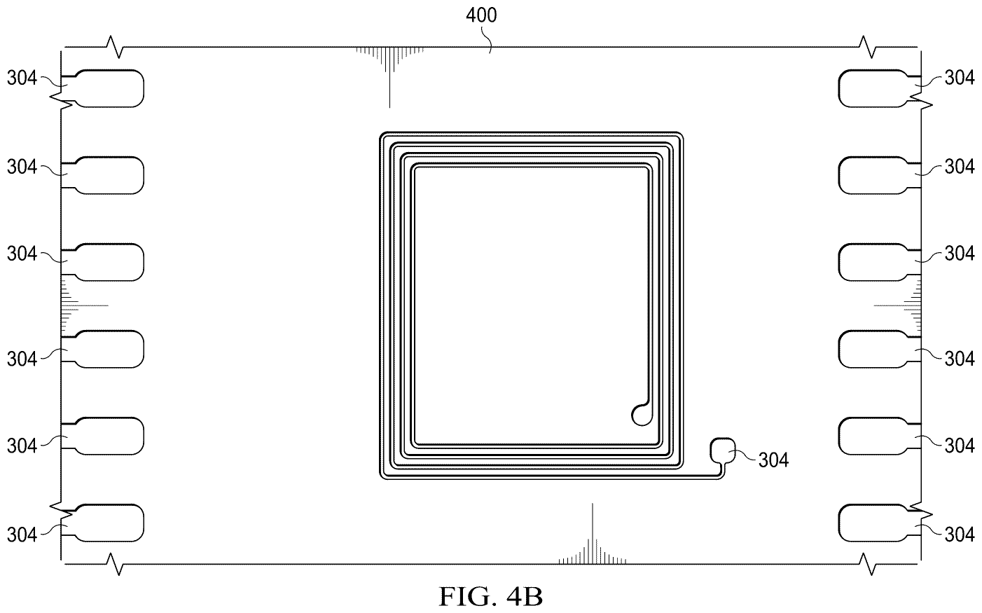

The method 200 may include patterning a dry film mask (202). FIG. 3A is a cross-sectional view of a carrier core 300. A barrier layer 302 contacts the carrier core 300. A seed layer 304 (e.g., copper) contacts the barrier layer 302. FIG. 3B is a top-down view of the structure of FIG. 3A. FIG. 4A is a cross-sectional view of the structure of FIG. 3A, except that a dry film mask 400 has been applied and patterned on the seed layer 304. FIG. 4B is a top-down view of the structure of FIG. 4A.

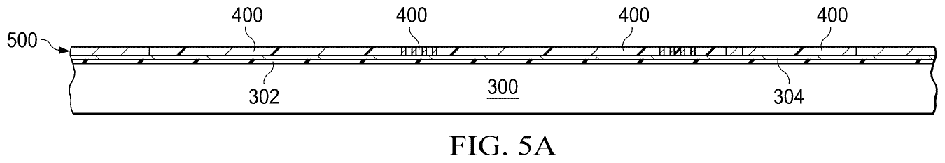

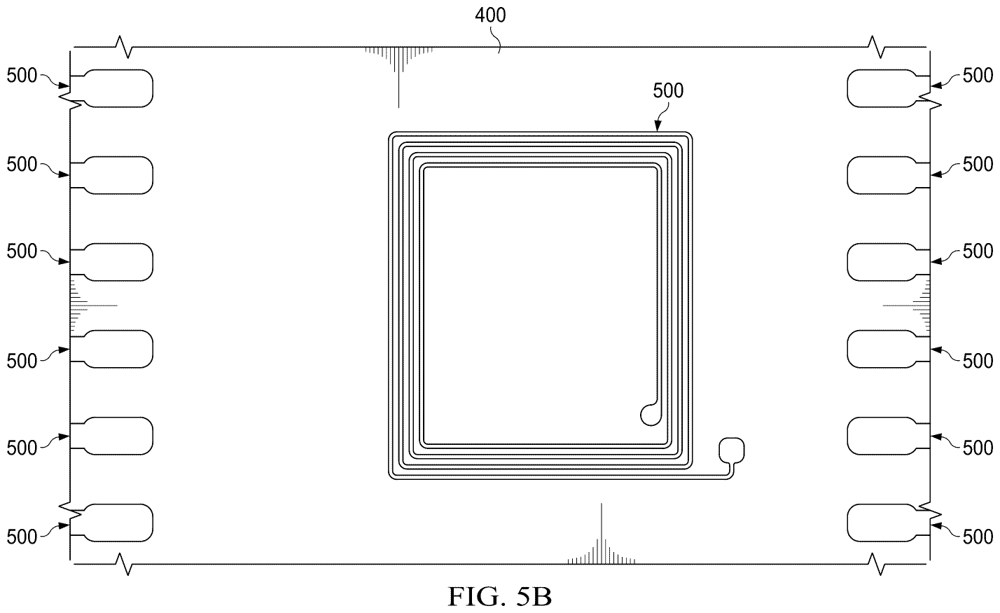

The method 200 may include plating a metal layer using the dry film mask (204). FIG. 5A is a cross-sectional view of the structure of FIG. 4A, except that a metal layer 500 (e.g., copper) has been plated in gaps of the dry film mask 400. This metal layer 500 may correspond to the metal layer 136, metal layer 142, and the coil 148 of FIG. 1A. FIG. 5B is a top-down view of the structure of FIG. 5A.

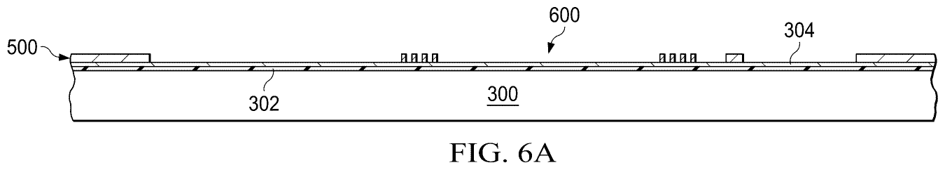

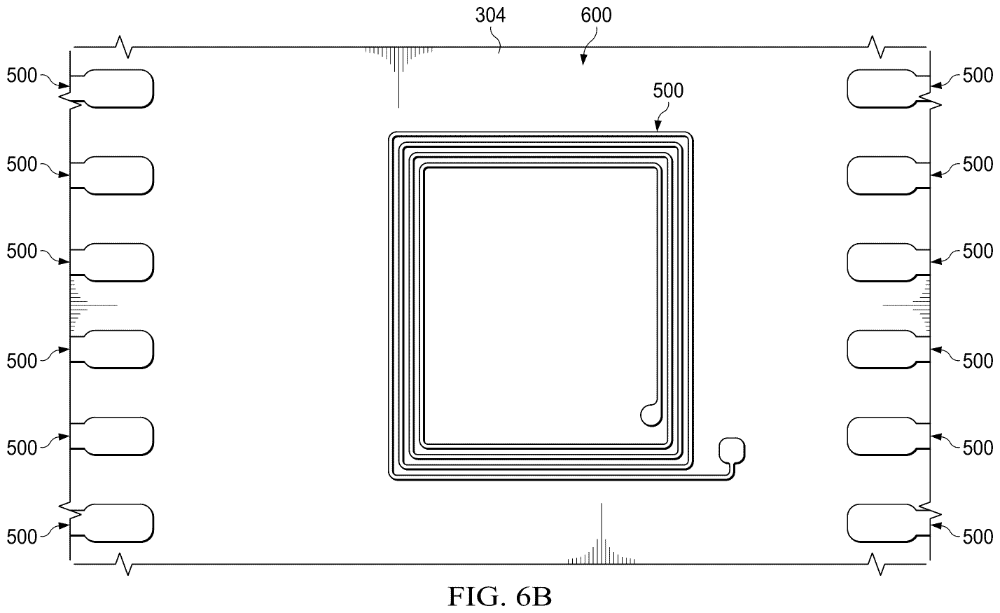

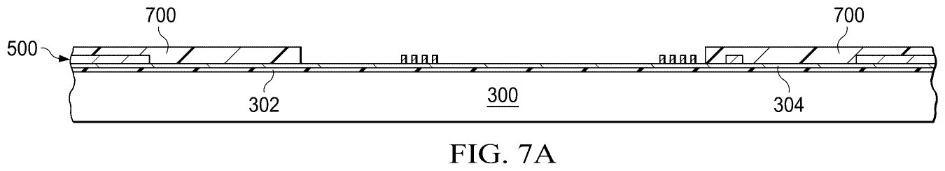

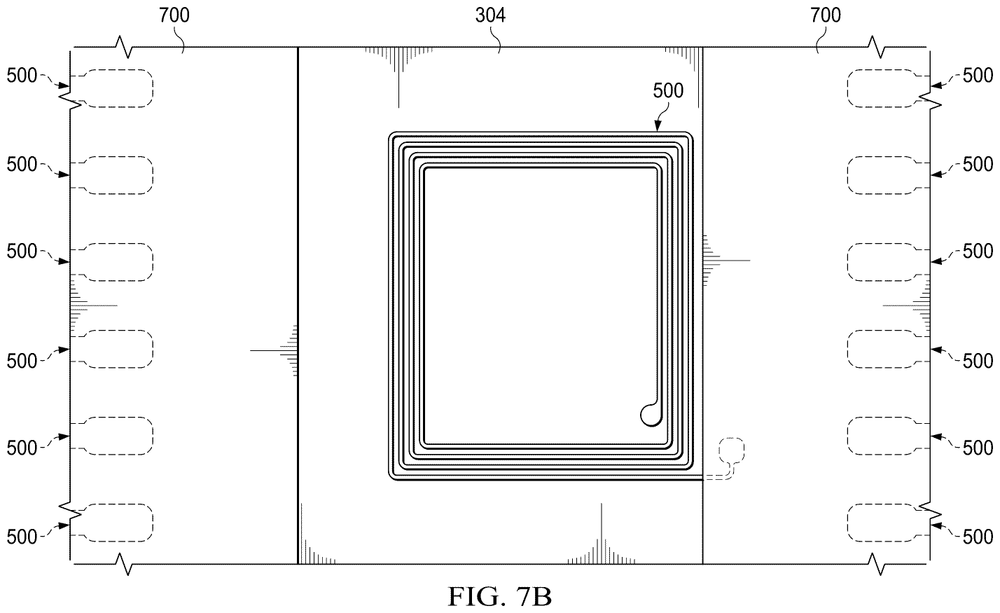

The method 200 may include removing the dry film mask (206) and applying a dry film mask on areas not to be covered by a BUF laminate (208). FIG. 6A is a cross-sectional view of the structure of FIG. 5A, except that the dry film mask of FIG. 5A has been removed, as numeral 600 depicts. FIG. 6B is a top-down view of the structure of FIG. 6A. FIG. 7A is a cross-sectional view of the structure of FIG. 6A, except that a dry film mask 700 is applied to areas that are not to be covered by a BUF laminate. FIG. 7B is a top-down view of the structure of FIG. 7A.

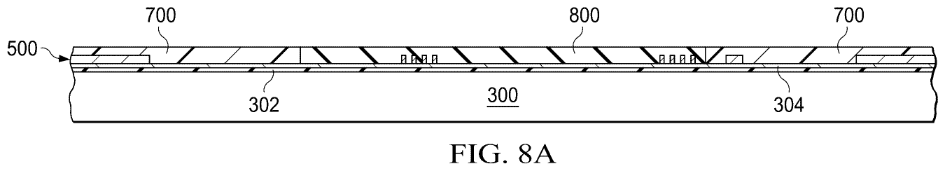

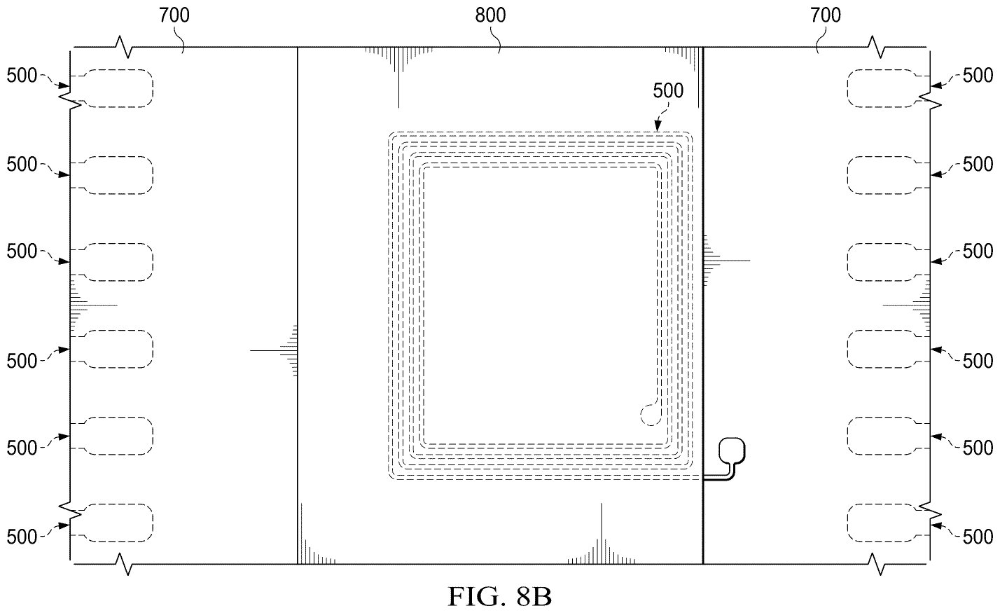

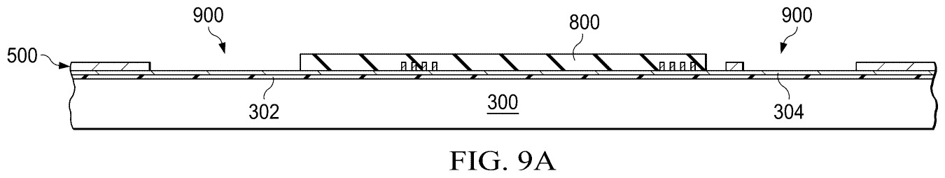

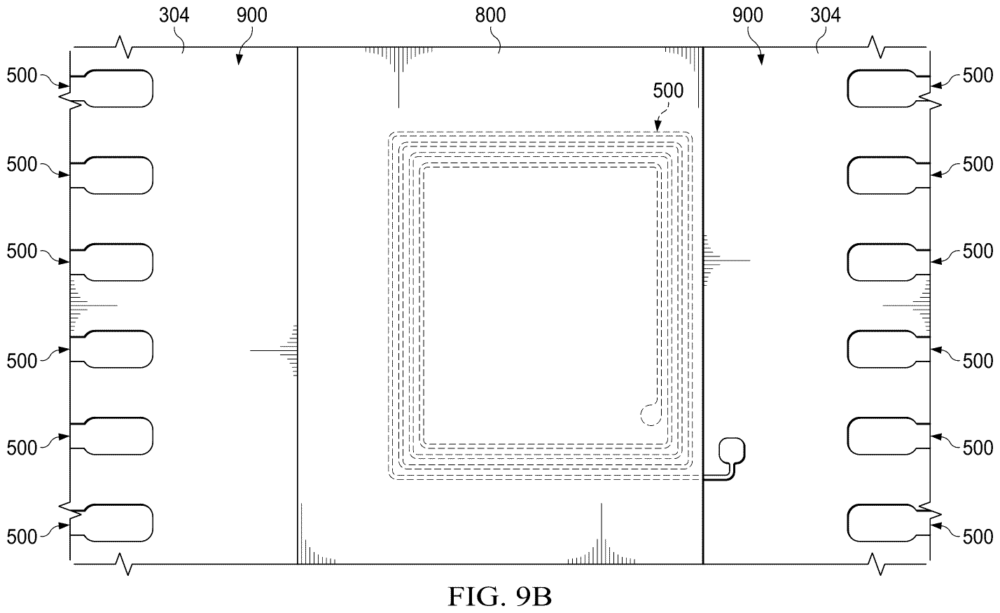

The method 200 may include laminating with a BUF (210) and removing the dry film mask (212). FIG. 8A is a cross-sectional view of the structure of FIG. 7A, except that a BUF 800 has been applied to the areas not covered by the dry film mask 700. FIG. 8B is a top-down view of the structure of FIG. 8A. FIG. 9A is a cross-sectional view of the structure of FIG. 8A, except that the dry film mask 700 has been removed, as numeral 900 indicates. FIG. 9B is a top-down view of the structure of FIG. 9A.

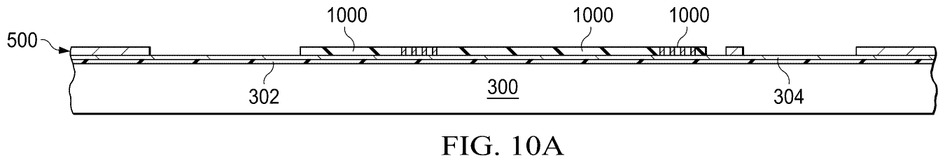

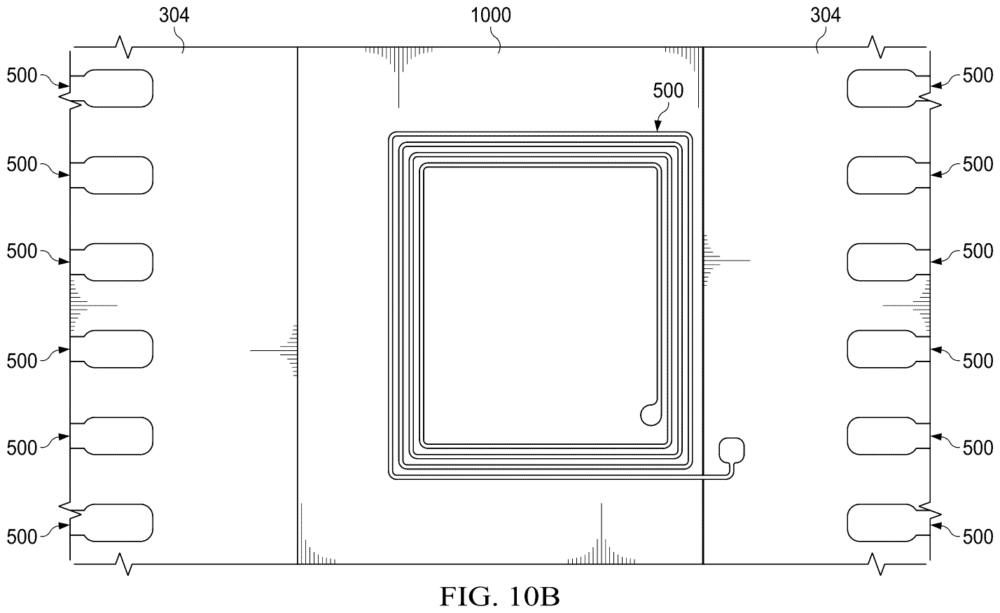

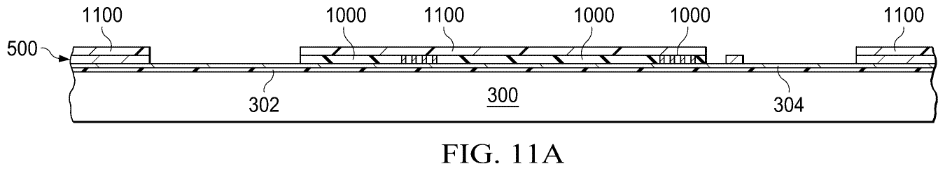

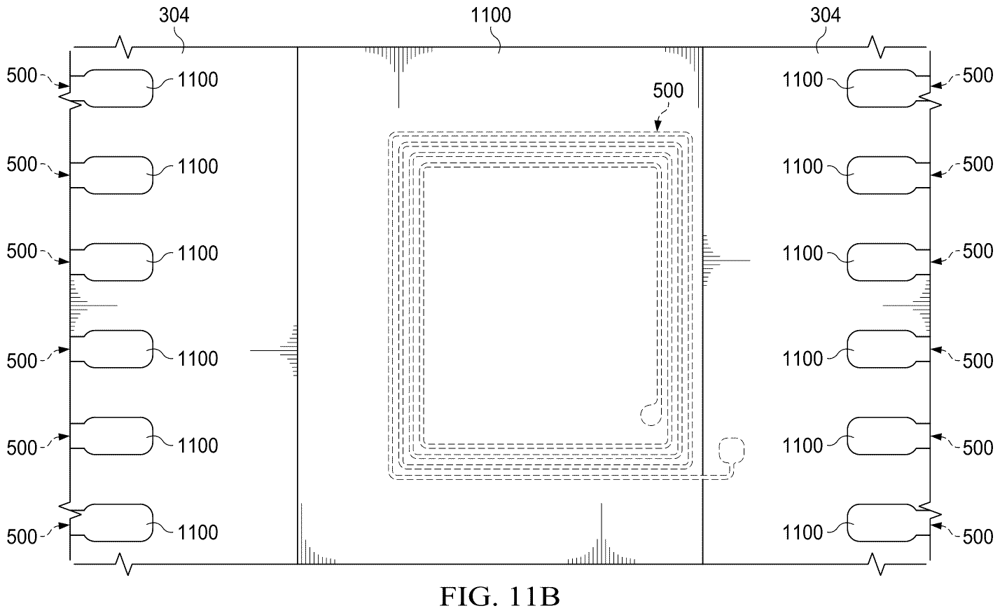

The method 200 may include thinning the BUF (214) and applying a dry film mask on areas that are not to be covered by a pre-preg laminate (216). FIG. 10A is a cross-sectional view of the structure of FIG. 9A, except that the BUF 800 has been thinned to produce the BUF 1000. For example, the BUF 800 may be thinner to a same thickness as the metal layer 500. FIG. 10B is a top-down view of the structure of FIG. 10A. FIG. 11A is a cross-sectional view of the structure of FIG. 10A, except that a dry film mask 1100 has been applied to areas not to be covered by pre-preg laminate. FIG. 11B is a top-down view of the structure of FIG. 11A.

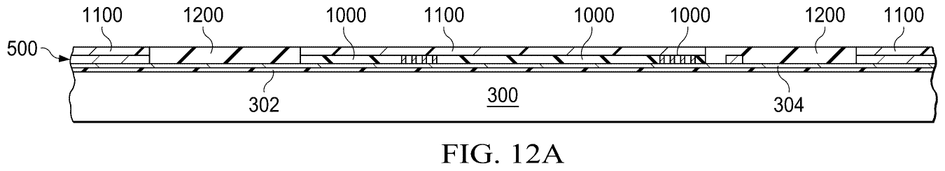

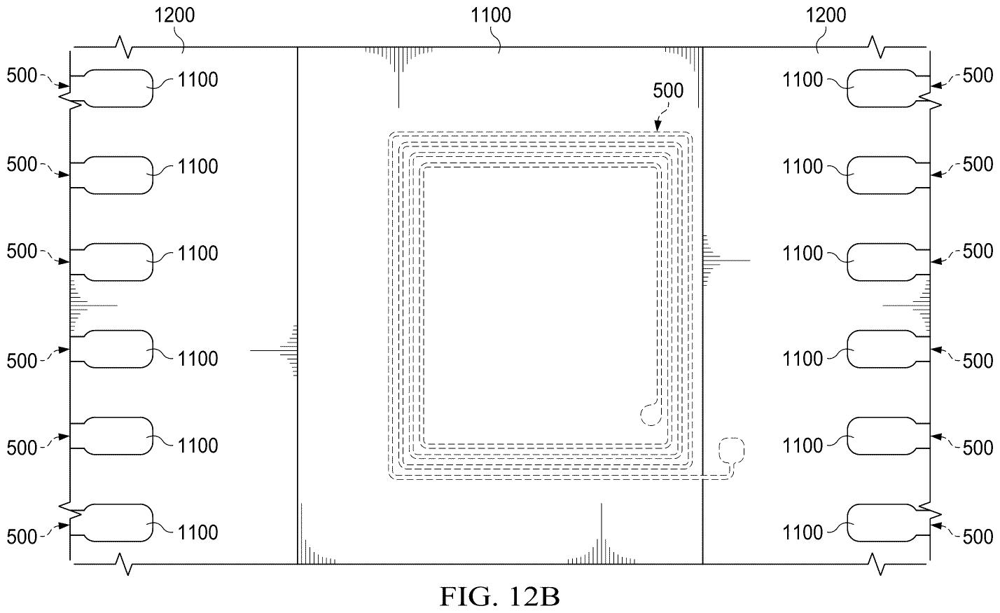

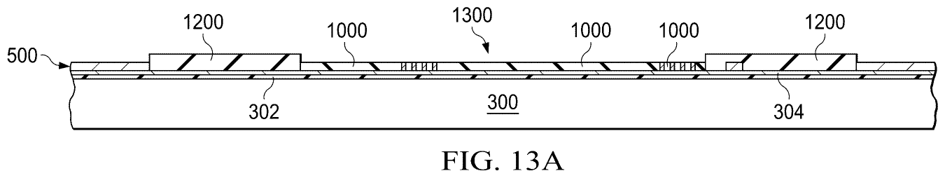

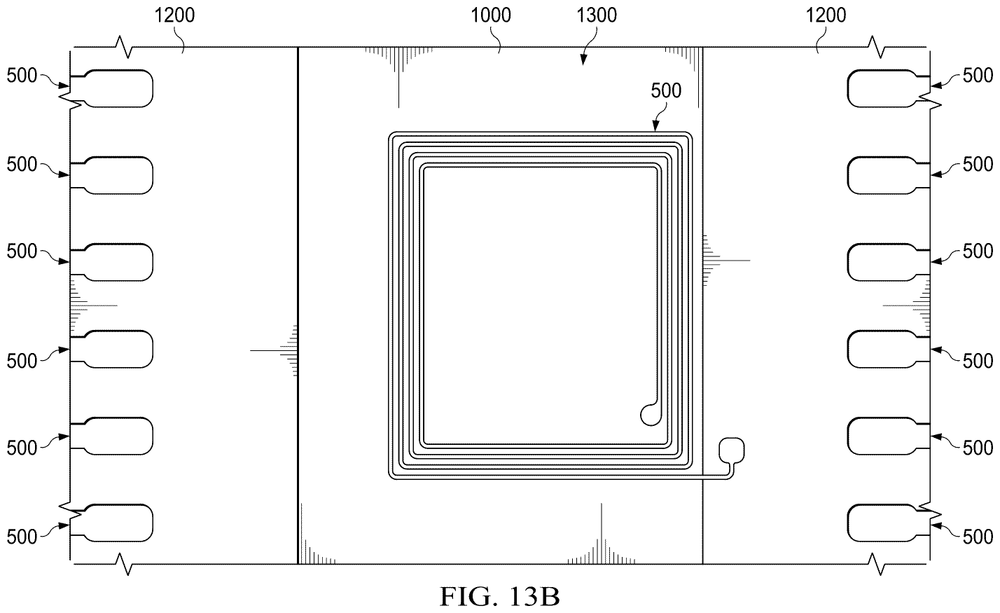

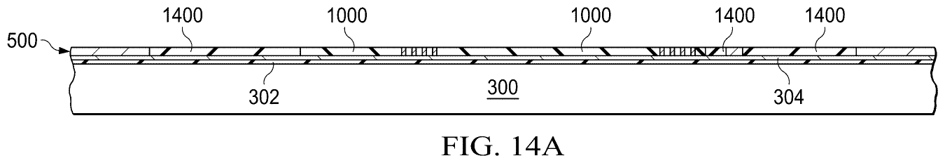

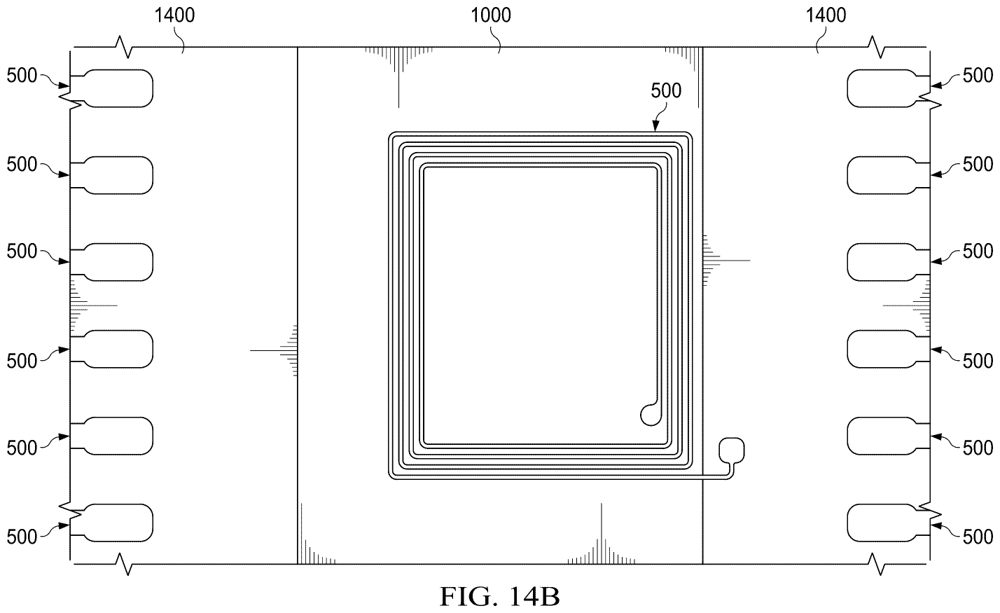

The method 200 may include laminating with pre-preg (218), removing the dry film mask (220), and thinning the pre-preg layer (222). FIG. 12A is a cross-sectional view of the structure of FIG. 11A, except that pre-preg layers 1200 are applied. FIG. 12B is a top-down view of the structure of FIG. 12A. FIG. 13A is a cross-sectional view of the structure of FIG. 12A, except that the dry film mask 1100 is removed, as numeral 1300 indicates. FIG. 13B is a top-down view of the structure of FIG. 13A. FIG. 14A is a cross-sectional view of the structure of FIG. 13A, except that the pre-preg layers 1200 are thinned, as numeral 1400 indicates. For example, the pre-preg layers 1200 may be thinned to have a same thickness as the BUF 1000. FIG. 14B is a top-down view of the structure of FIG. 14A.

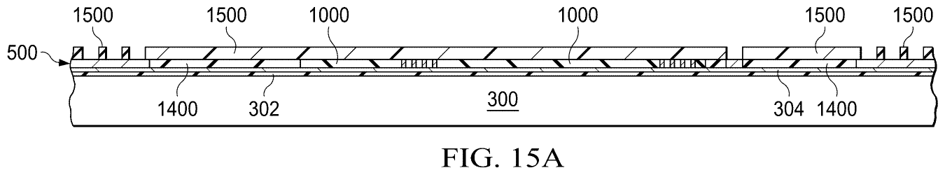

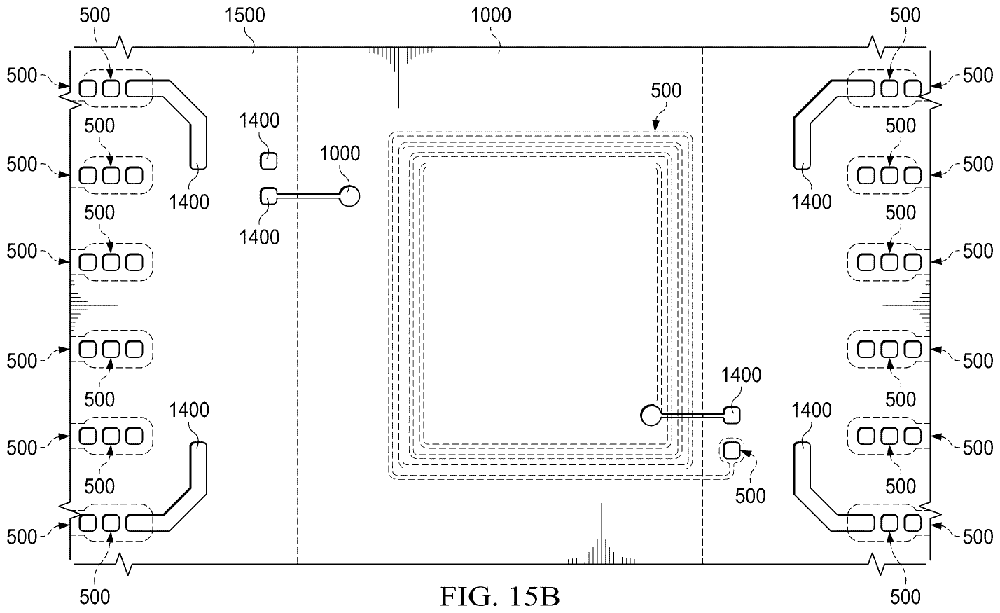

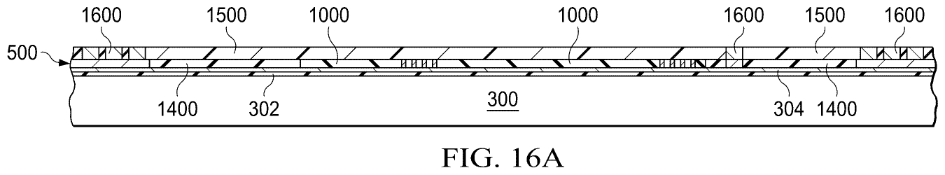

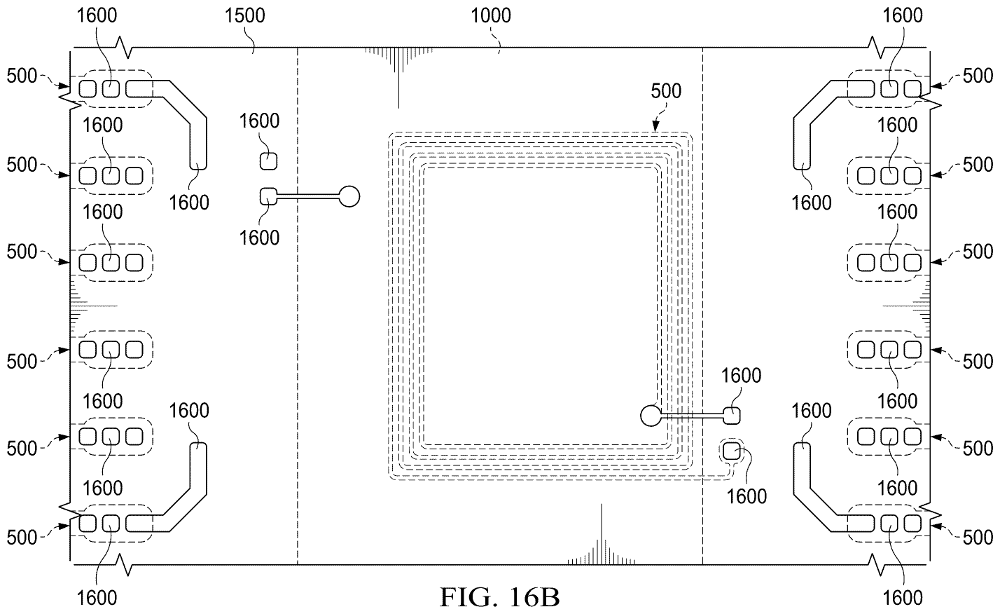

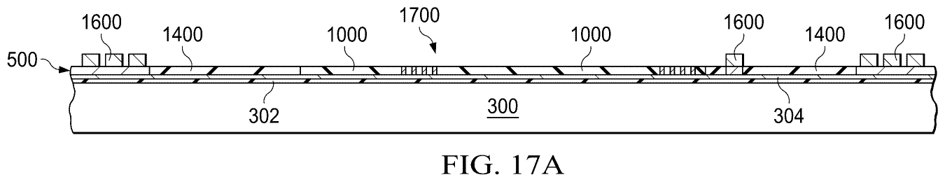

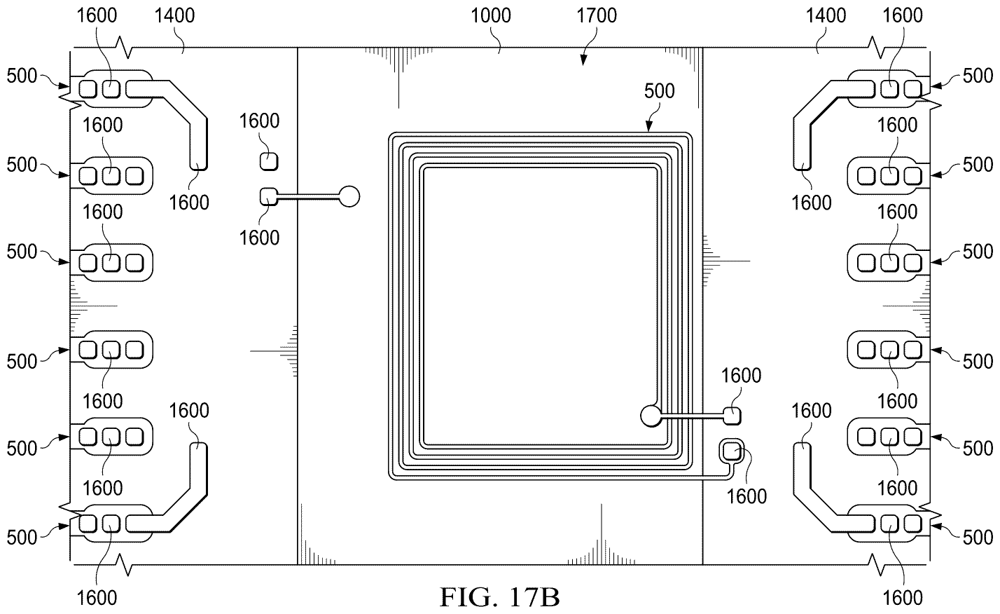

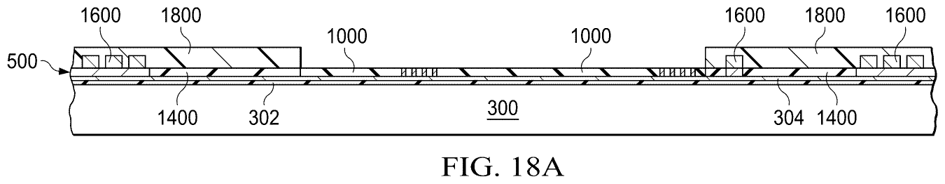

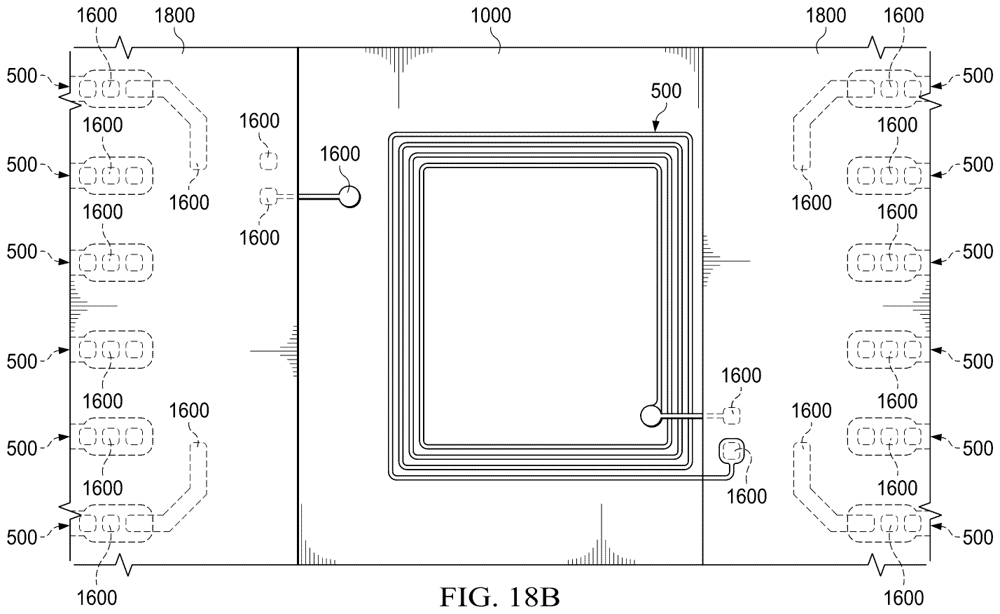

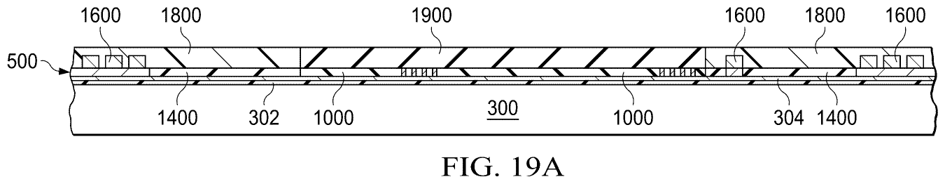

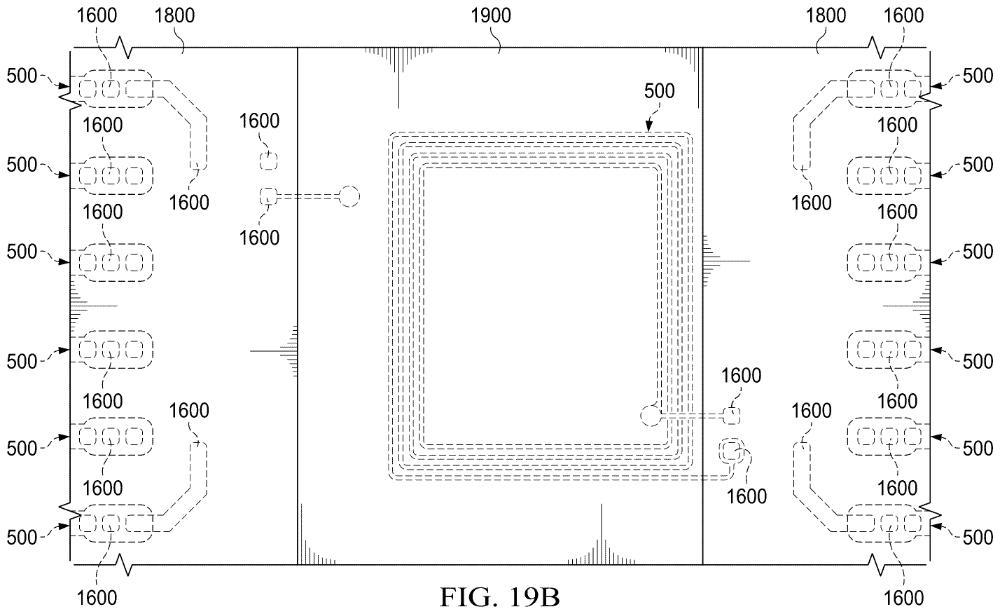

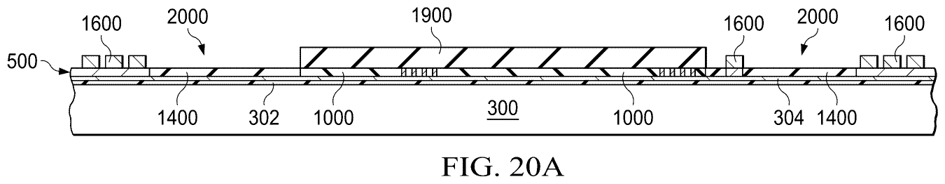

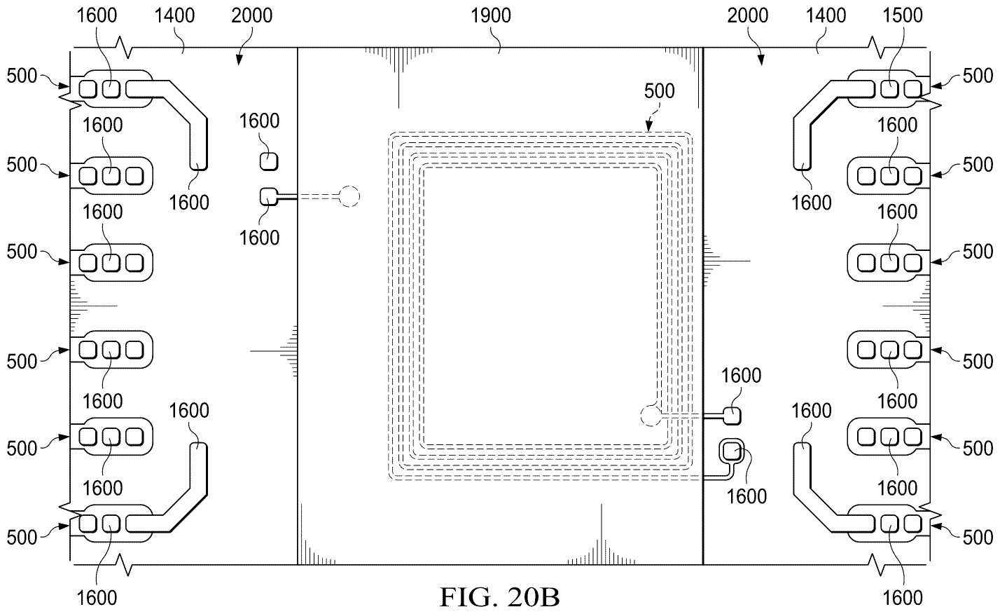

The method 200 may include determining whether additional metal layers are to be formed (224). If so, the steps 202-224 are iterated until all metal layers that are to be formed have been formed. In example process flow being described, two additional metal layers are formed. Specifically, FIG. 15A is a cross-sectional view of the structure of FIG. 14A, except that a dry-film mask 1500 is applied and patterned. FIG. 15B is a top-down view of the structure of FIG. 15A. FIG. 16A is a cross-sectional view of the structure of FIG. 15A, except that metal components 1600 (e.g., vias 140, 146, portions of coil 148) are plated using the dry film mask 1500. FIG. 16B is a top-down view of the structure of FIG. 16A. FIG. 17A is a cross-sectional view of the structure of FIG. 16A, except that the dry film mask 1500 is removed, as numeral 1700 indicates. FIG. 17B is a top-down view of the structure of FIG. 17A. FIG. 18A is a cross-sectional view of the structure of FIG. 17A, except that a dry film mask 1800 is applied to areas not to be covered by the BUF. FIG. 18B is a top-down view of the structure of FIG. 18A. FIG. 19A is a cross-sectional view of the structure of FIG. 18A, except that additional BUF 1900 is applied to the existing BUF. FIG. 19B is a top-down view of the structure of FIG. 19A. FIG. 20A is a cross-sectional view of the structure of FIG. 19A, except that the dry film mask 1800 is removed, as numeral 2000 indicates. FIG. 20B is a top-down view of the structure of FIG. 20A.

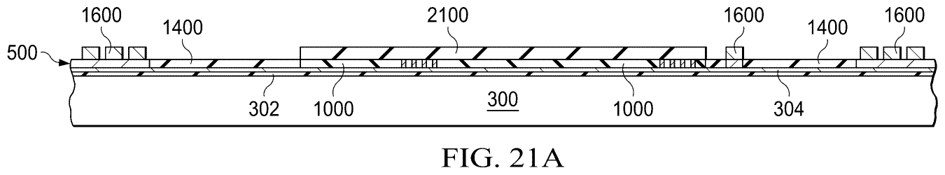

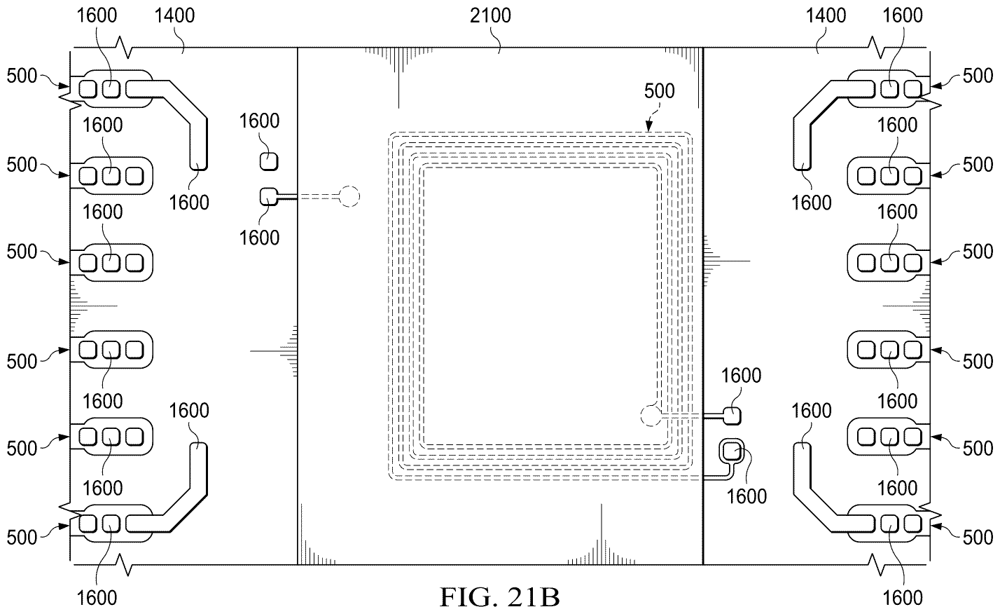

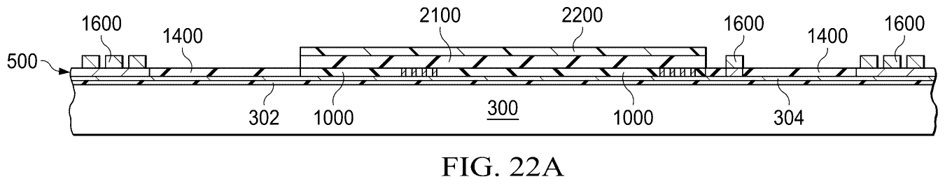

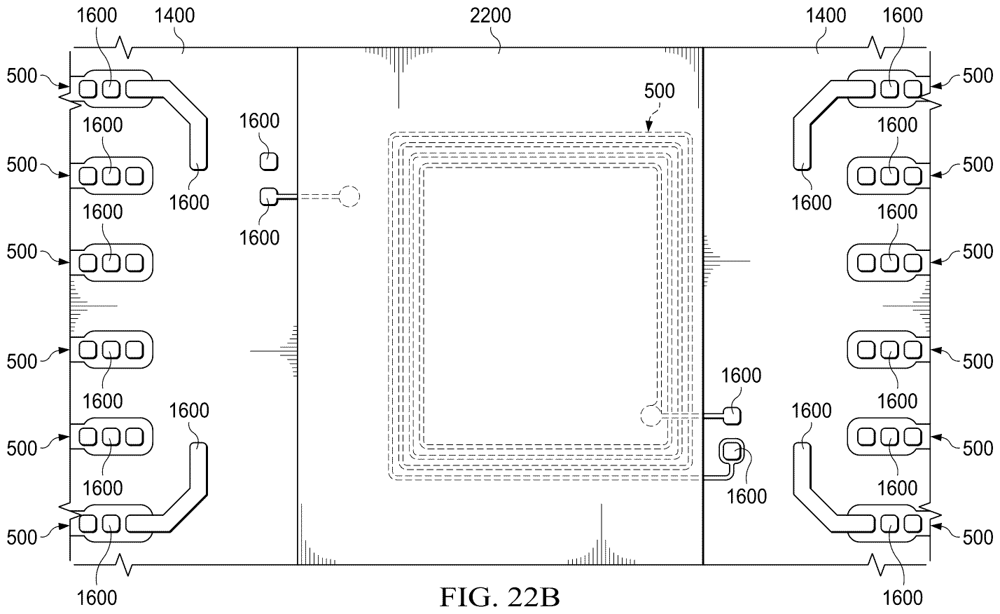

FIG. 21A is a cross-sectional view of the structure of FIG. 20A, except that the BUF 1900 is thinned to a thickness matching the metal components 1600 to produce a BUF 2100. FIG. 21B is a top-down view of the structure of FIG. 21A. FIG. 22A is a cross-sectional view of the structure of FIG. 21A, except that a dry film mask 2200 is applied to the BUF 2100. FIG. 22B is a top-down view of the structure of FIG. 22A.

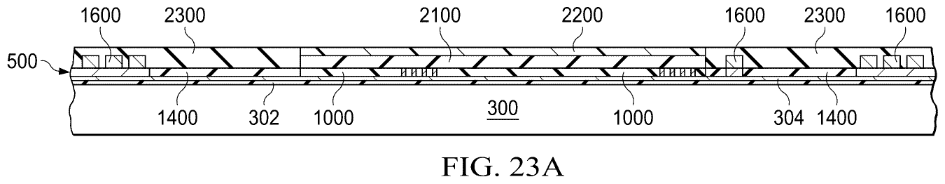

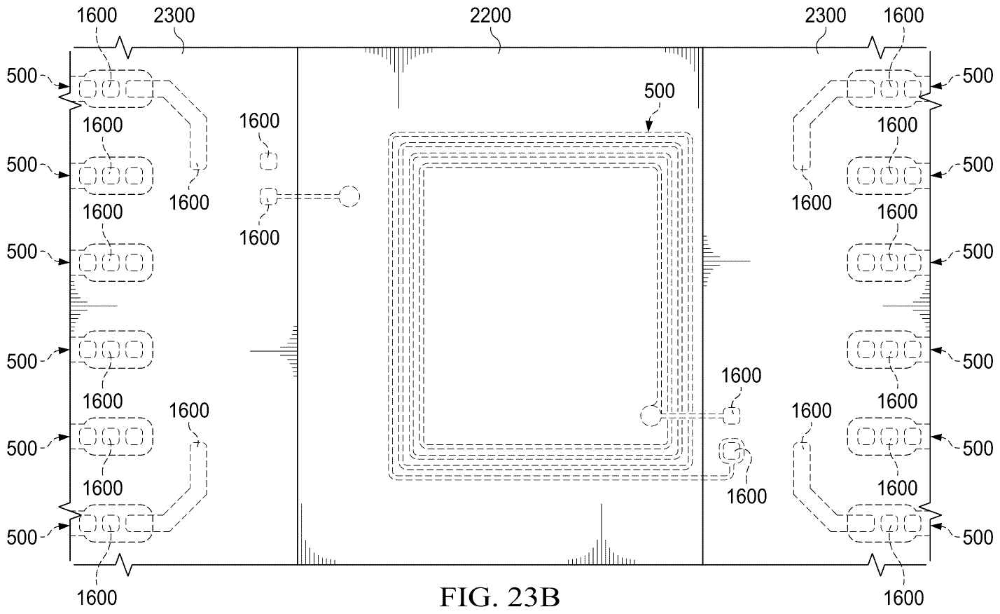

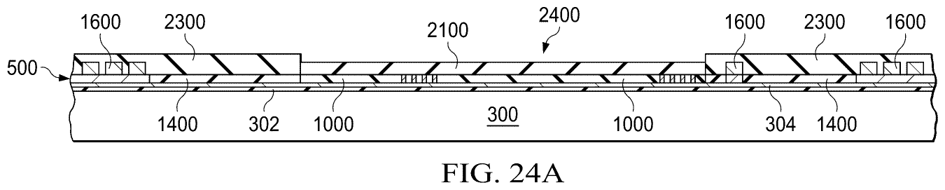

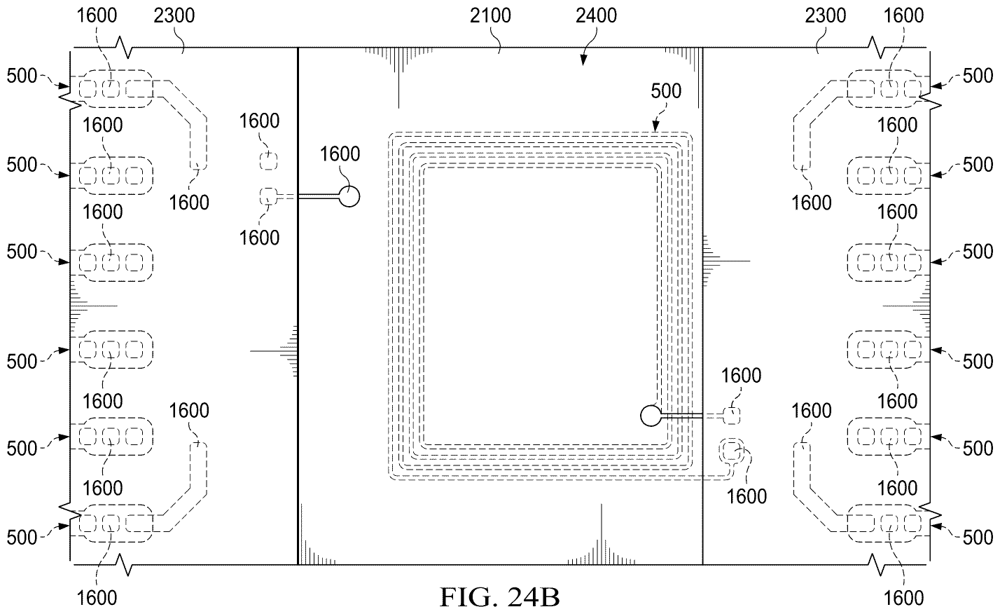

FIG. 23A is a cross-sectional view of the structure of FIG. 22A, except that additional pre-preg 2300 is applied to areas not covered by the dry film mask 2200, as shown. FIG. 23B is a top-down view of the structure of FIG. 23A. FIG. 24A is a cross-sectional view of the structure of FIG. 23A, except that the dry film mask 2200 is removed, as numeral 2400 indicates. FIG. 24B is a top-down view of the structure of FIG. 24A.

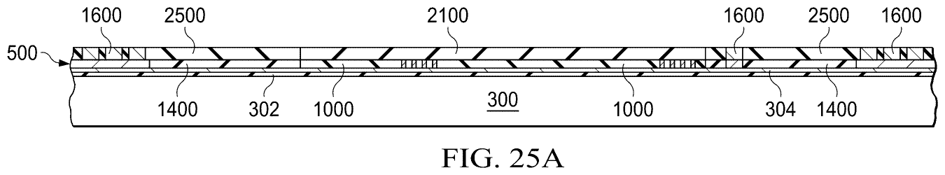

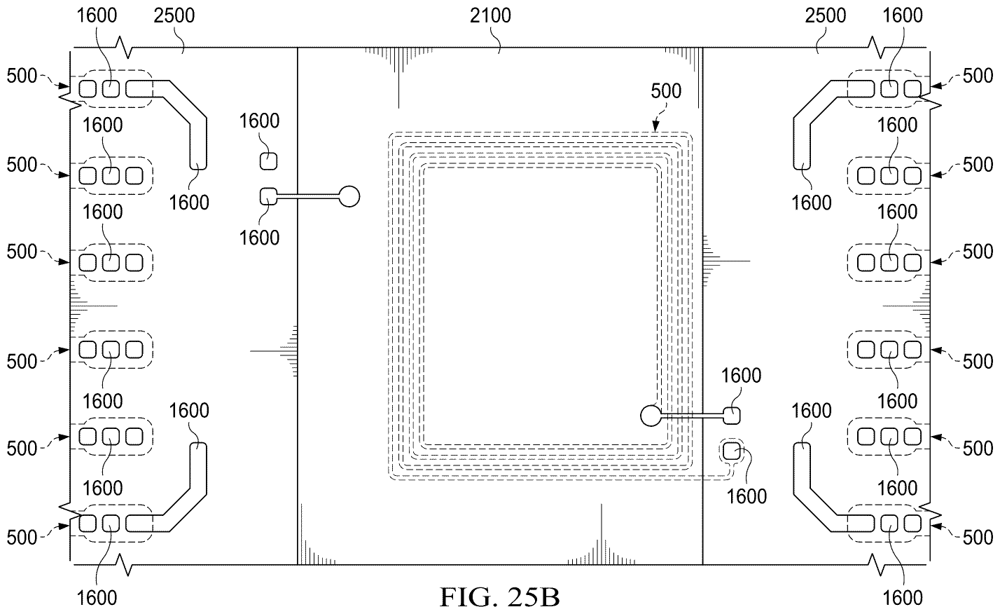

FIG. 25A is a cross-sectional view of the structure of FIG. 24A, except that the pre-preg 2300 is thinned to a thickness of the BUF 2100 to produce pre-preg layers 2500. FIG. 25B is a top-down view of the structure of FIG. 25A.

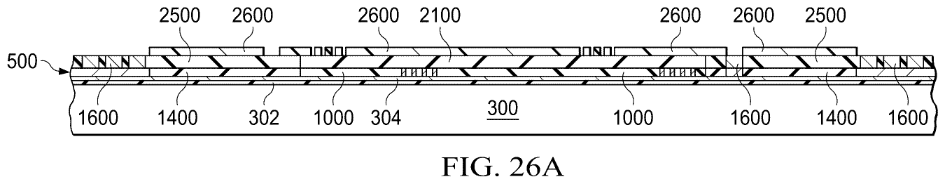

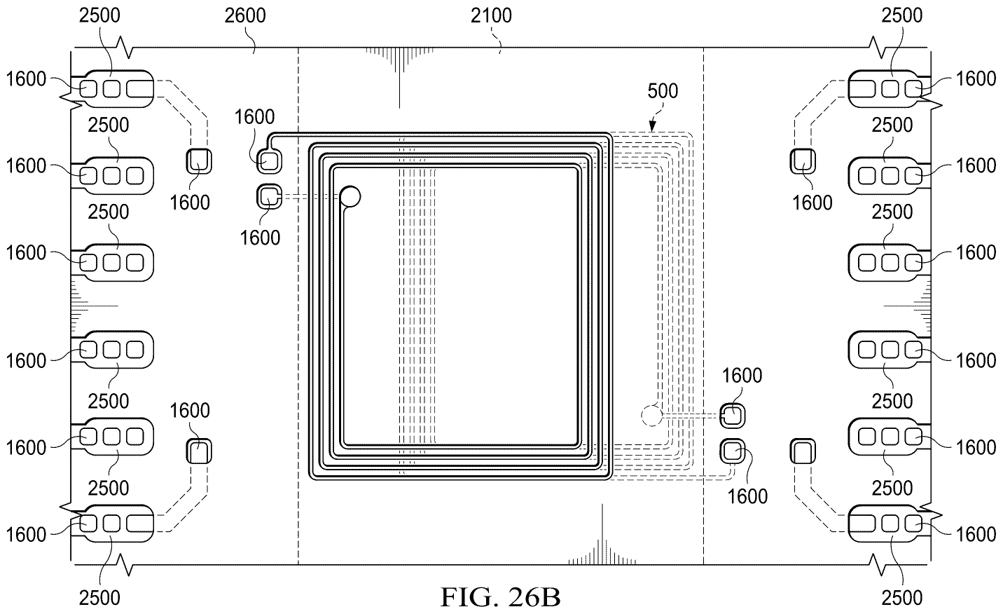

FIG. 26A is a cross-sectional view of the structure of FIG. 25A, except that a dry film mask 2600 is applied and patterned. FIG. 26B is a top-down view of the structure of FIG. 26A.

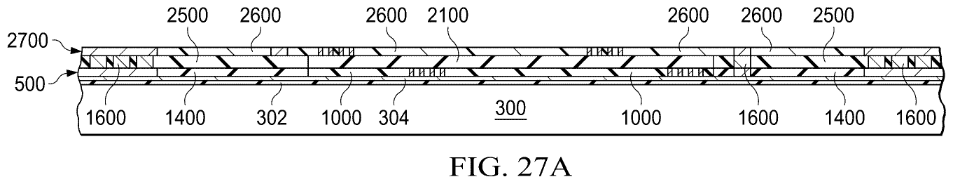

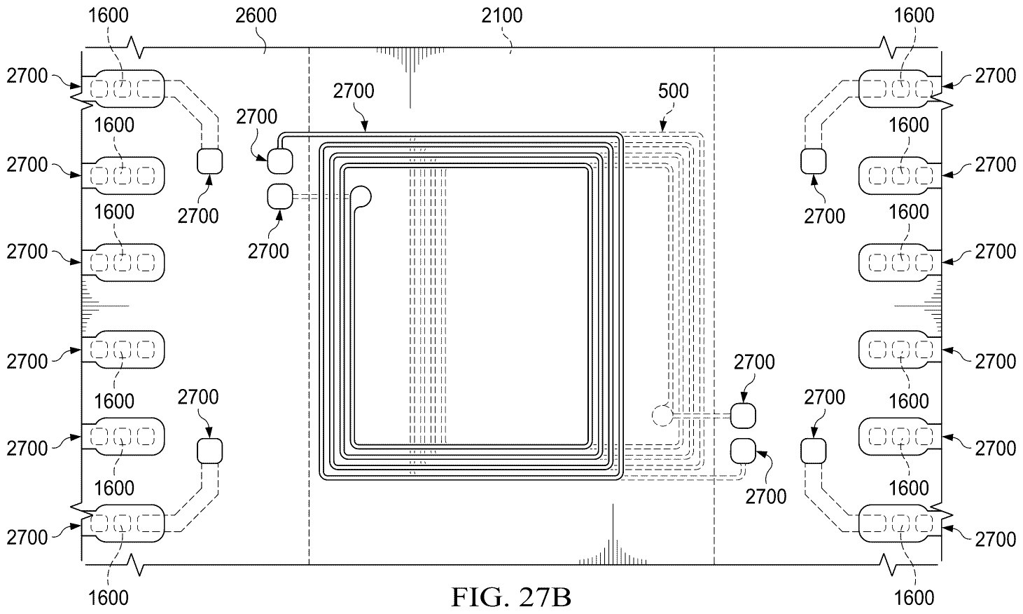

FIG. 27A is a cross-sectional view of the structure of FIG. 26A, except that a metal layer 2700 is plated using the dry film mask 2600. The metal layer 2700 may correspond to the metal layers 138, 144 and the coil 150 in FIG. 1A. FIG. 27B is a top-down view of the structure of FIG. 27A.

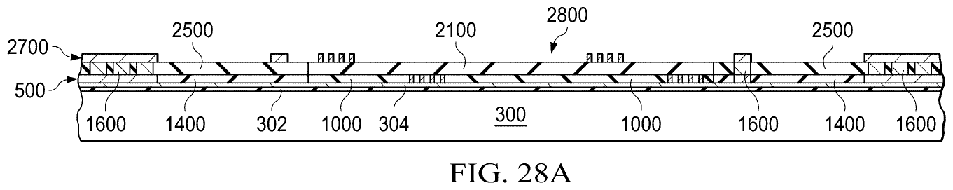

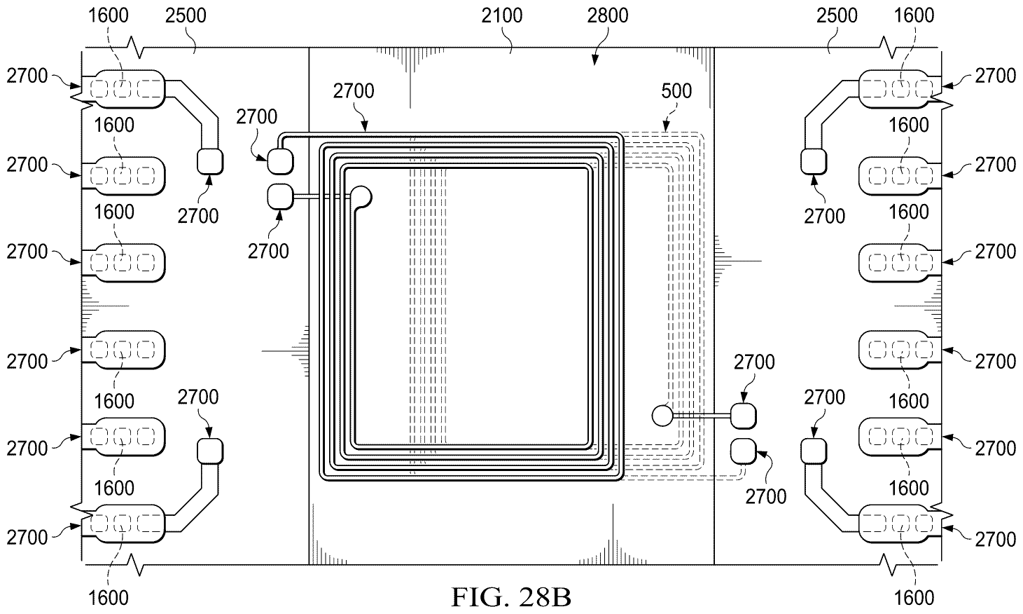

FIG. 28A is a cross-sectional view of the structure of FIG. 27A, except that the dry film mask 2600 is removed, as numeral 2800 indicates. FIG. 28B is a top-down view of the structure of FIG. 28A.

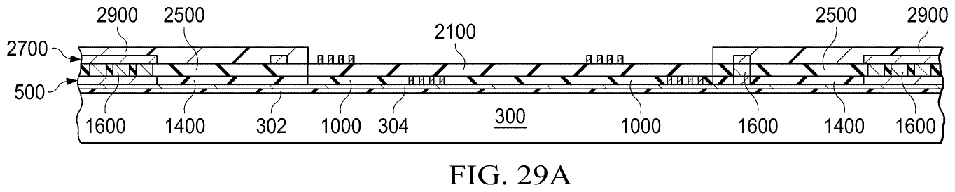

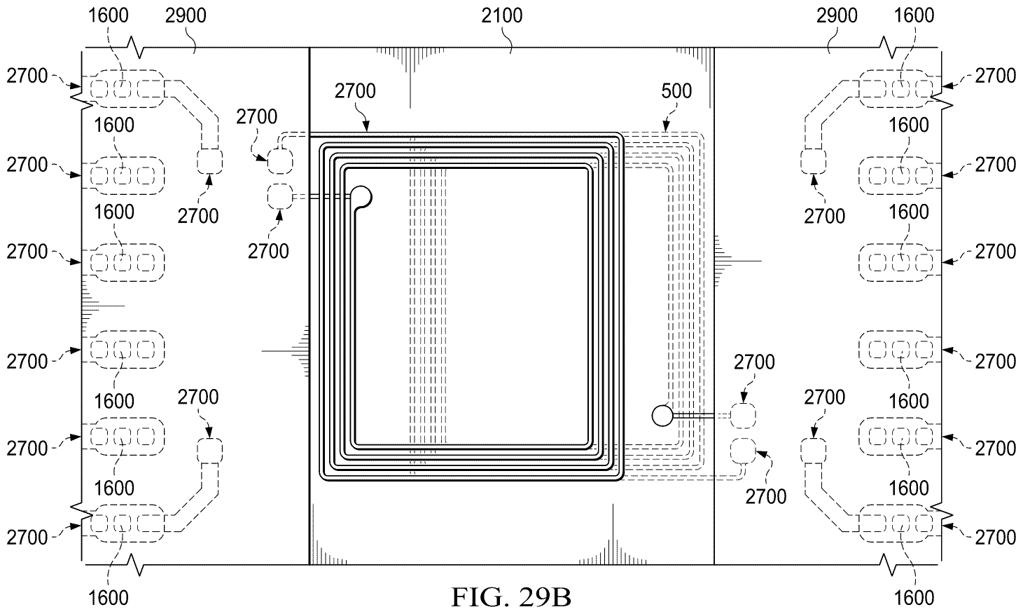

FIG. 29A is a cross-sectional view of the structure of FIG. 28A, except that a dry film mask 2900 is applied to areas where additional BUF is not to be applied. FIG. 29B is a top-down view of the structure of FIG. 29A.

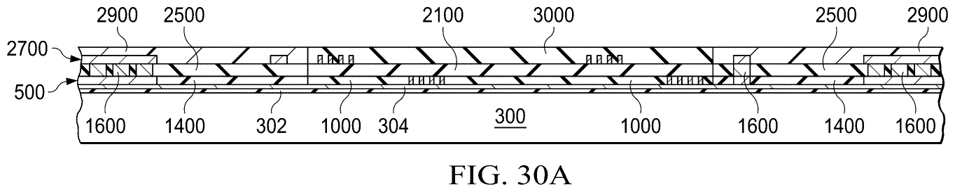

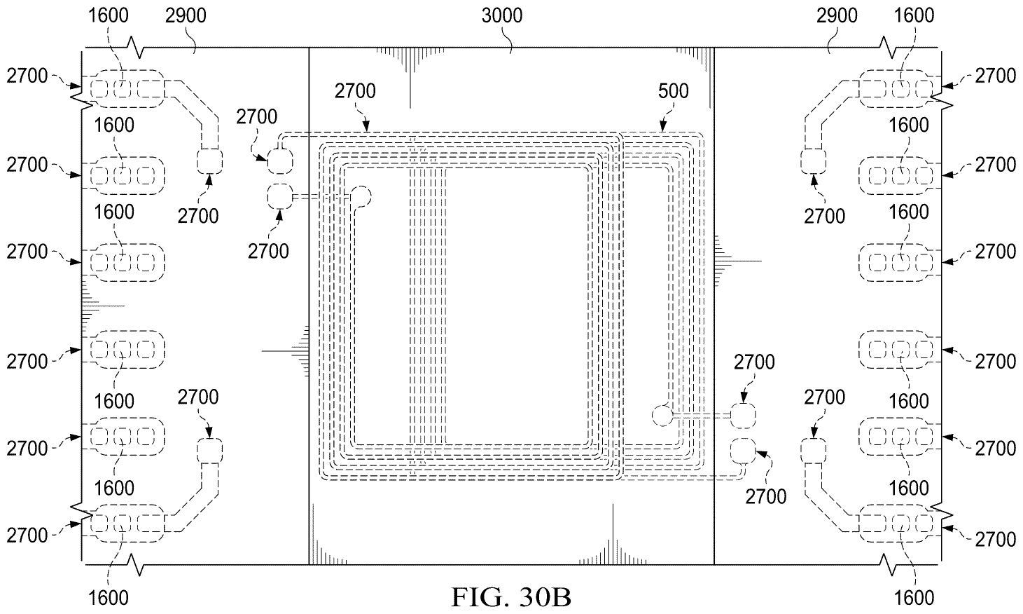

FIG. 30A is a cross-sectional view of the structure of FIG. 29A, except that additional BUF 3000 is applied on areas not covered by the dry film mask 2900. FIG. 30B is a top-down view of the structure of FIG. 30A.

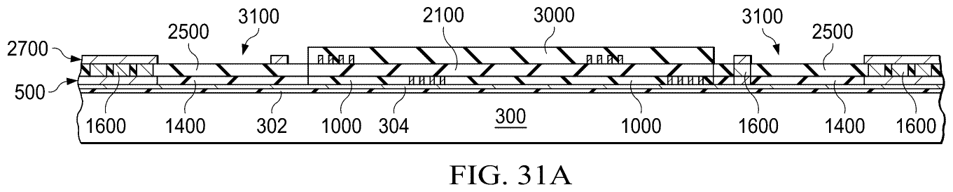

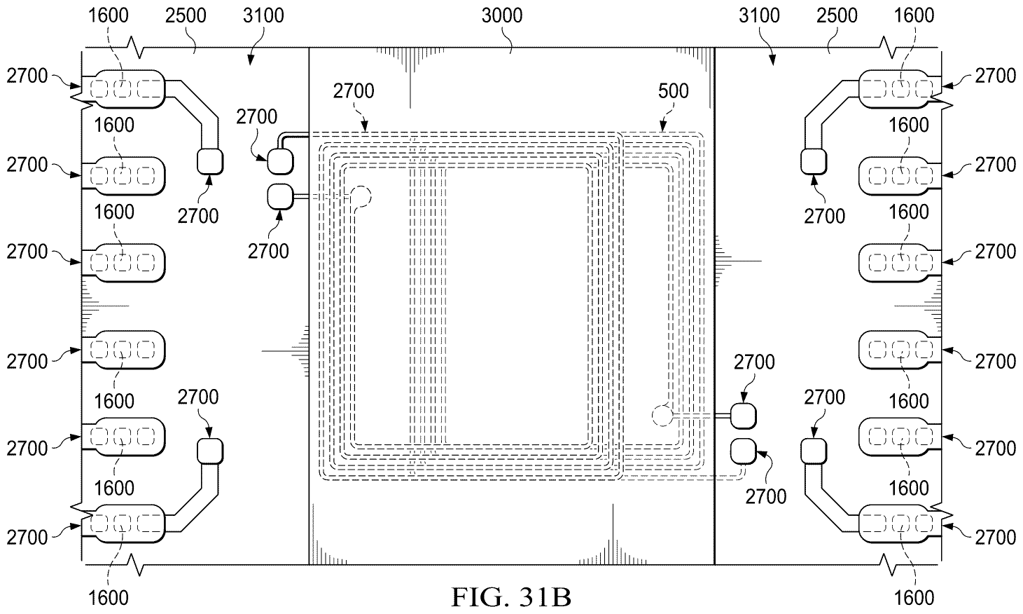

FIG. 31A is a cross-sectional view of the structure of FIG. 30A, except that the dry film mask 2900 is removed, as numeral 3100 indicates. FIG. 31B is a top-down view of the structure of FIG. 31A.

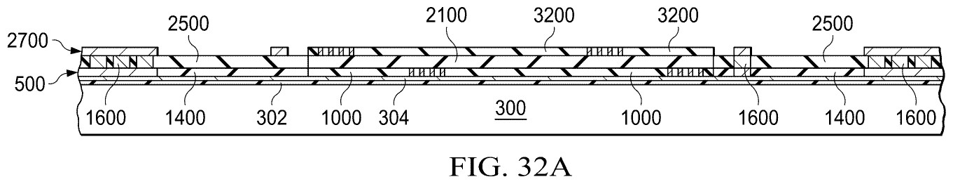

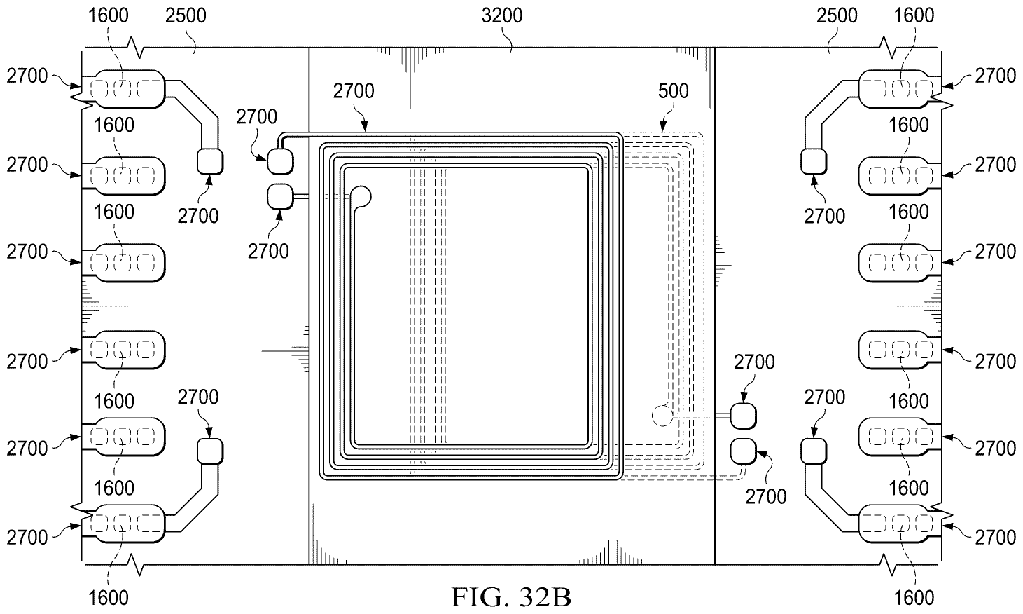

FIG. 32A is a cross-sectional view of the structure of FIG. 31A, except that the BUF 3000 is thinned to a thickness of the metallization 124 and/or 128, as the thinned BUF 3200 indicates. FIG. 32B is a top-down view of the structure of FIG. 32A.

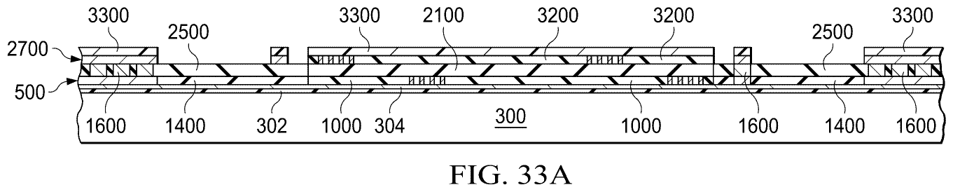

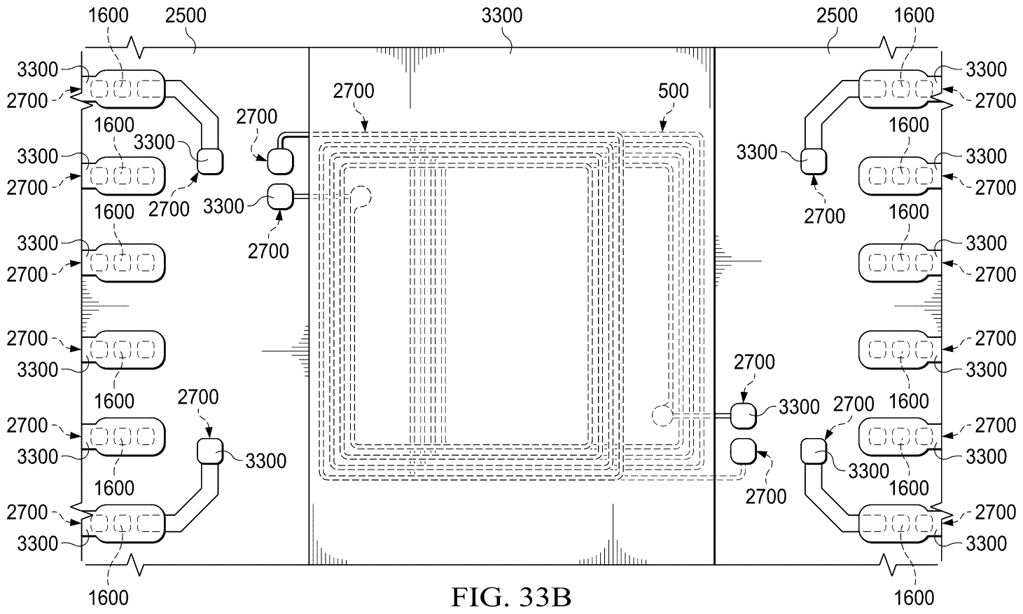

FIG. 33A is a cross-sectional view of the structure of FIG. 32A, except that a dry film mask 3300 is applied to areas that are to be protected from additional pre-preg deposition. FIG. 33B is a top-down view of the structure of FIG. 33A.

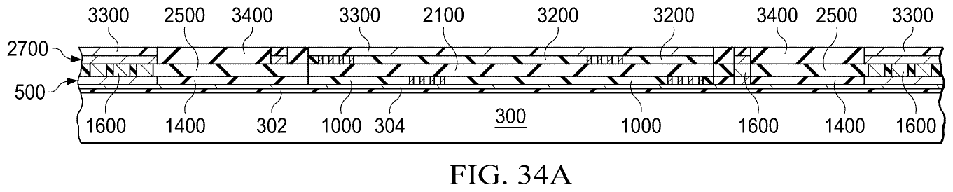

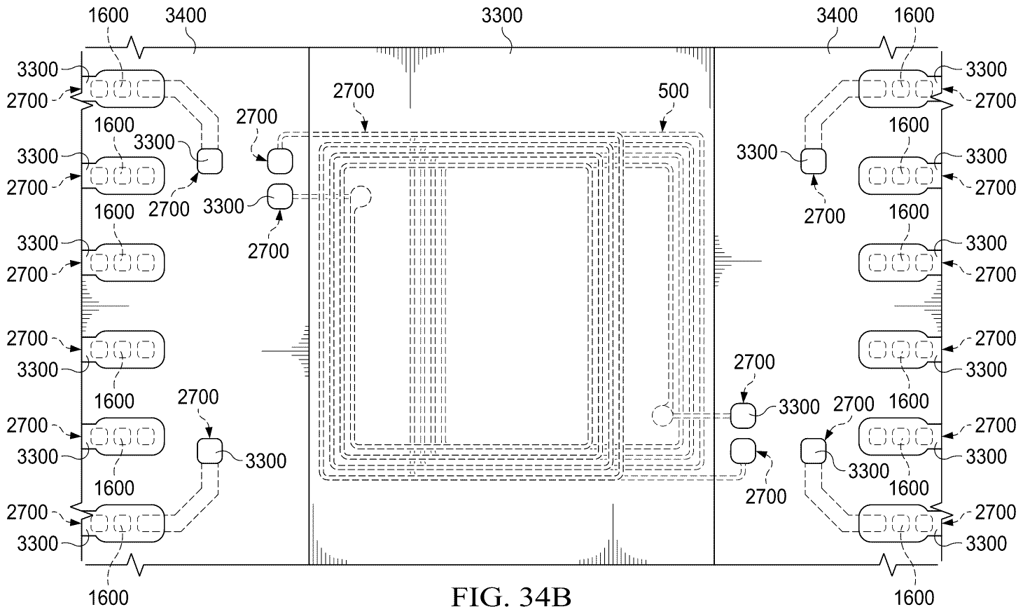

FIG. 34A is a cross-sectional view of the structure of FIG. 33A, except that additional pre-preg 3400 is applied to the areas not covered by the dry film mask 3300. FIG. 34B is a top-down view of the structure of FIG. 34A.

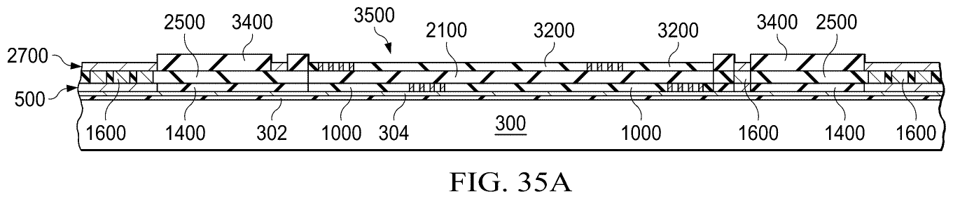

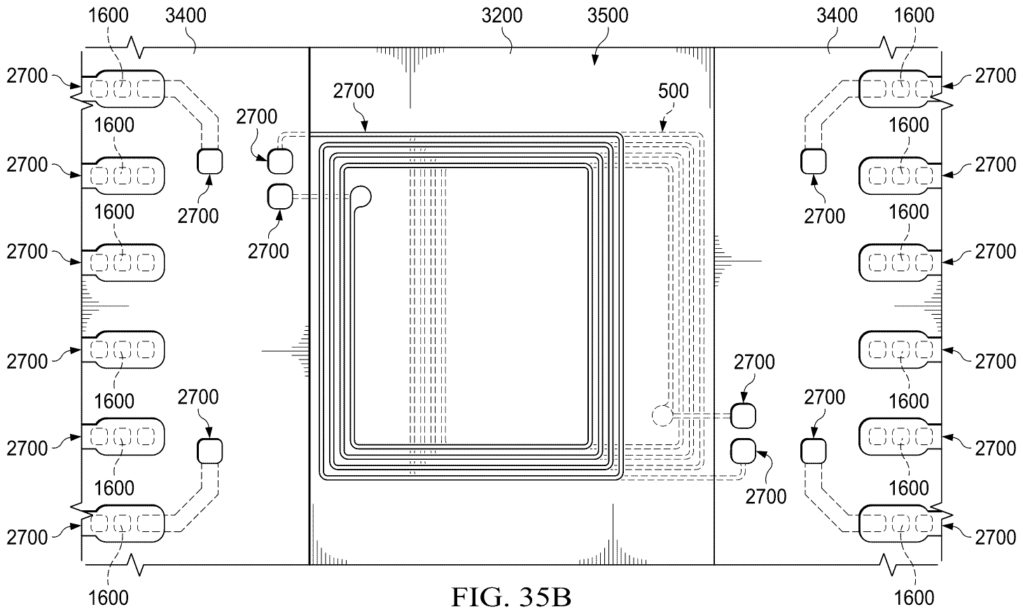

FIG. 35A is a cross-sectional view of the structure of FIG. 34A, except that the dry film mask 3300 is removed, as numeral 3500 indicates. FIG. 35B is a top-down view of the structure of FIG. 35A.

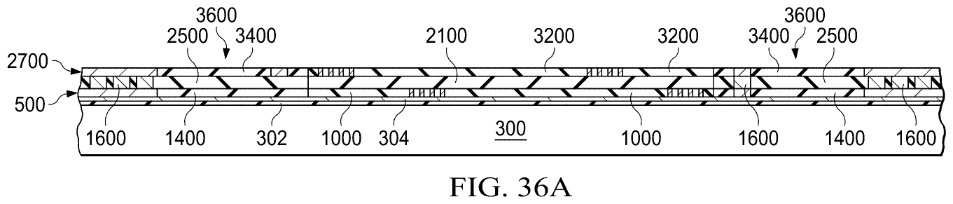

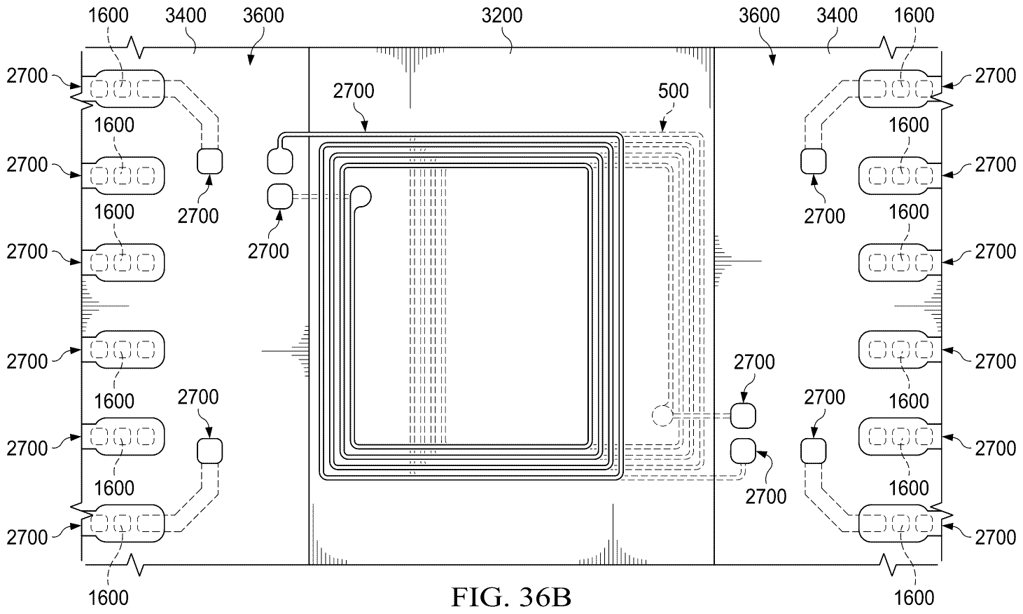

FIG. 36A is a cross-sectional view of the structure of FIG. 35A, except that the pre-preg 3400 is thinned to a thickness of the BUF 3200, as numeral 3600 indicates. FIG. 36B is a top-down view of the structure of FIG. 36A.

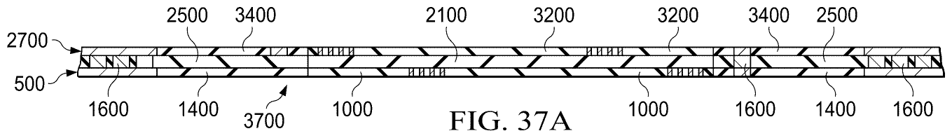

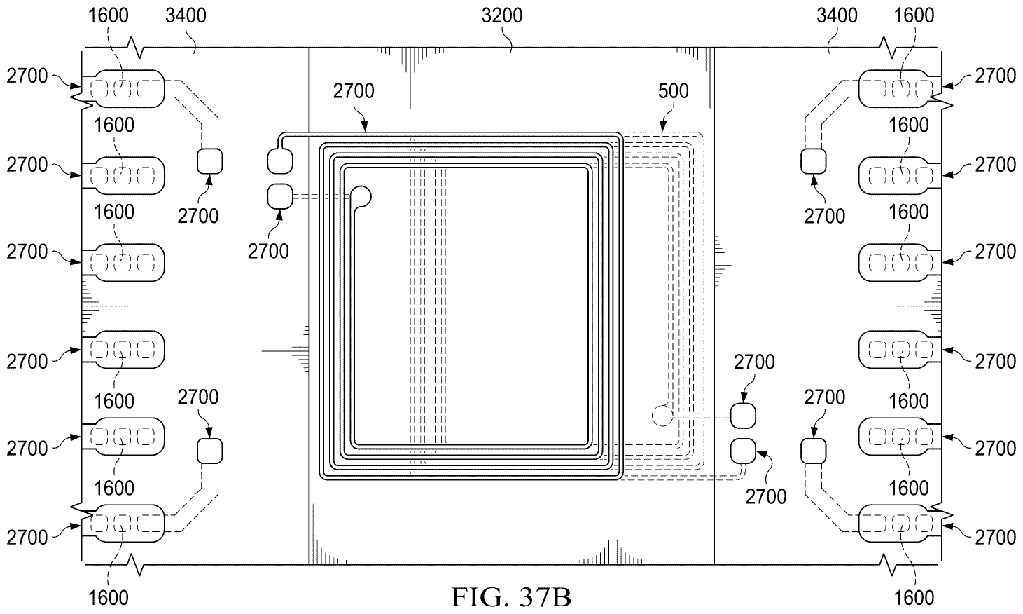

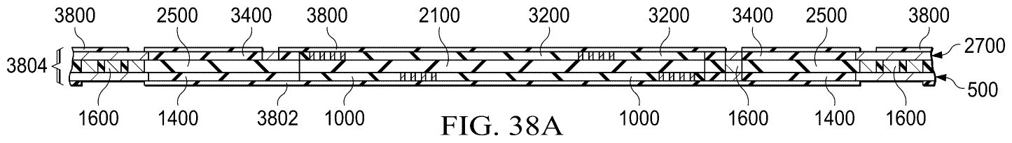

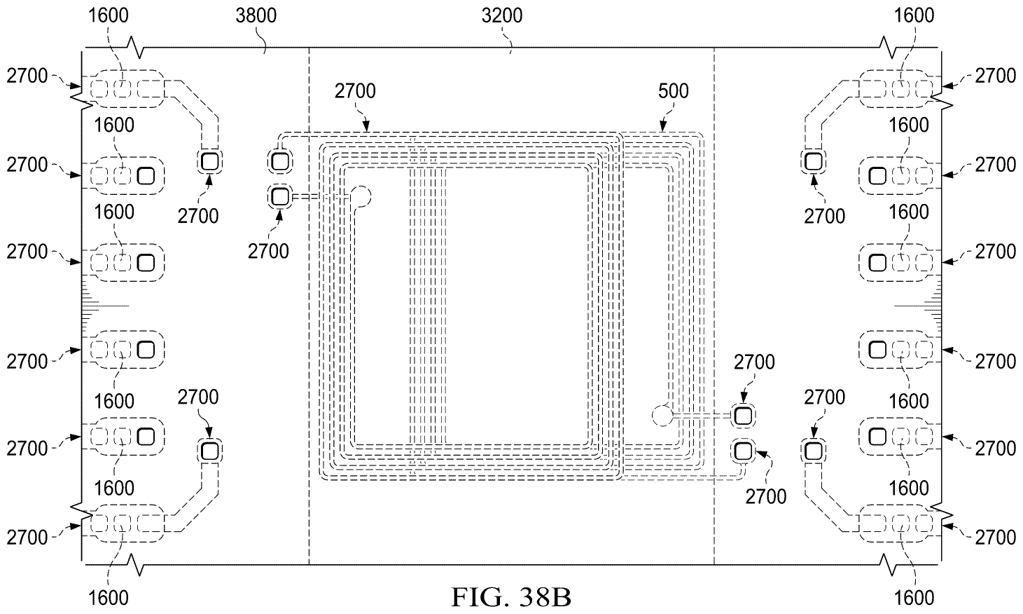

In this way, the steps 202-224 are iteratively performed until all metal layers are formed. The method 200 comprises removing the carrier core (226) and applying solder masks (228). FIG. 37A is a cross-sectional view of the structure of FIG. 36A, except that the carrier core 300, the barrier layer 302, and the seed layer 304 are removed, as numeral 3700 indicates. FIG. 37B is a top-down view of the structure of FIG. 37A. FIG. 38A is a cross-sectional view of the structure of FIG. 37A, except that solder masks 3800 and 3802 are applied on opposing top and bottom surfaces of the structure of FIG. 37A and are patterned. In examples, the solder masks 3800 and 3802 are patterned to expose specific portions of the metallizations within the substrate to facilitate soldering (e.g., to couple the substrate to semiconductor dies or to a printed circuit board (PCB)). The result is a completed substrate 3804. FIG. 38B is a top-down view of the structure of FIG. 38A.

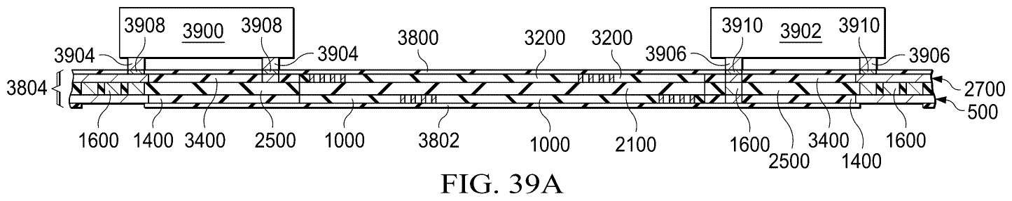

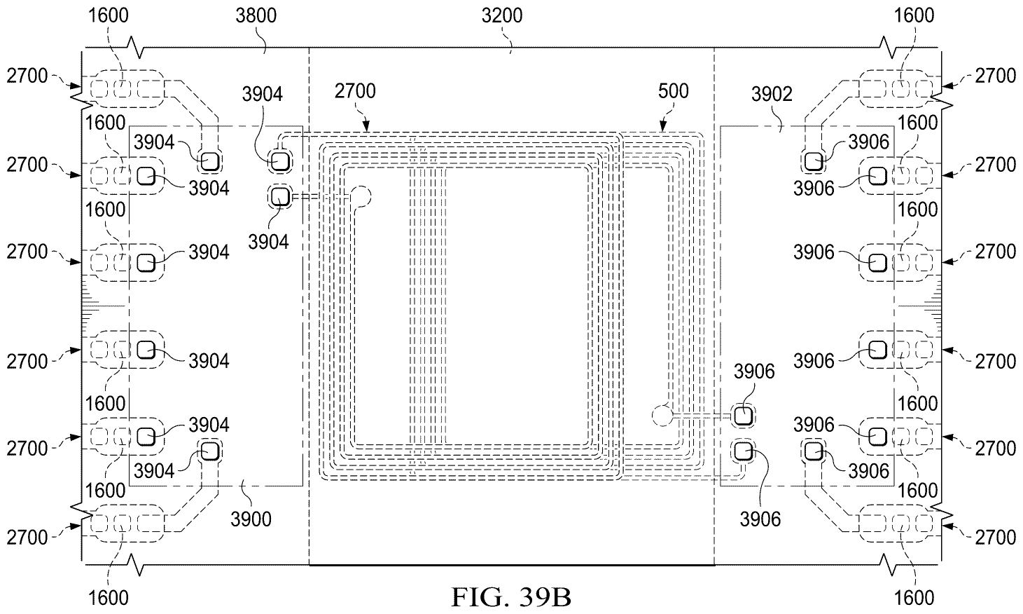

The method 200 includes coupling semiconductor dies to the metal layer(s) in the substrate (230), and covering the semiconductor dies and the substrate with a mold compound (232). FIG. 39A is a cross-sectional view of the structure of FIG. 38A, except that semiconductor dies 3900 and 3902 are coupled to the metallizations within the substrate 3804 using the pillars 3904 and 3906, respectively. Solder members 3908 may be useful to couple the pillars 3904 to the metallization(s) of the substrate 3804, and solder members 3910 may be useful to couple the pillars 3906 to the metallization(s) of the substrate 3804. For example, the solder members 3908 and 3910 may be positioned using the solder mask 3800, and after the pillars 3904, 3906 and semiconductor dies 3900, 3902 are positioned appropriately, the solder members 3908 and 3910 may be reflowed to establish connections to the metallizations within the substrate 3804. FIG. 39B is a top-down view of the structure of FIG. 39A.

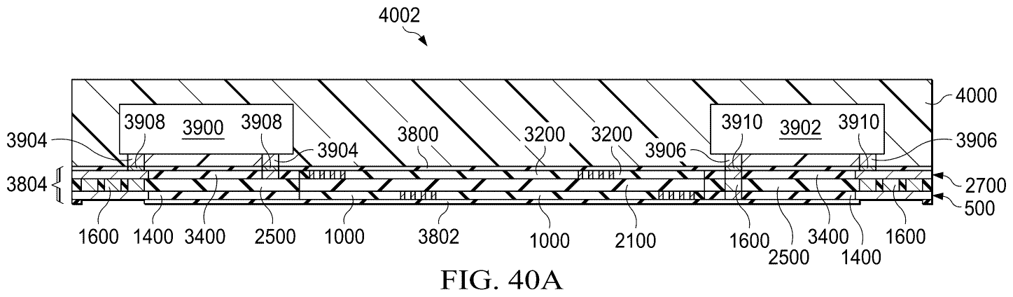

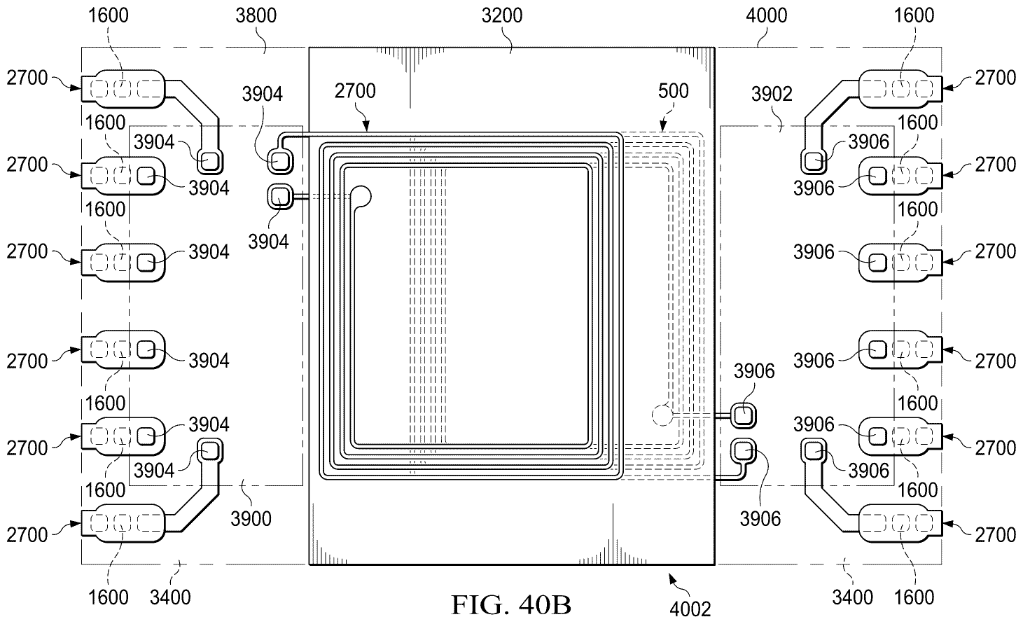

FIG. 40A is a cross-sectional view of the structure of FIG. 39A, except that a mold compound 4000 has been applied to the semiconductor dies 3900, 3902 and to the substrate 3804. FIG. 40B is a top-down view of the structure of FIG. 40A. The result is a completed semiconductor package 4002. The semiconductor package 4002 may be similar or identical to the semiconductor package 100 of FIGS. 1A-1C.

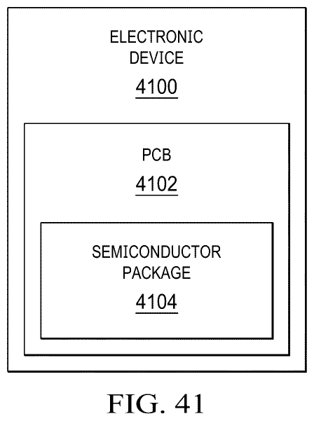

FIG. 41 is a block diagram of an electronic device including a semiconductor package having a BUF and pre-preg substrate, in accordance with various examples. Specifically, FIG. 41 illustrates an electronic device 4100 containing a PCB 4102 to which a semiconductor package 4104 is coupled. The semiconductor package 4104 may be similar or identical to the semiconductor packages 100 and/or 4002, described above. Examples of the electronic device 4100 include an automobile, an aircraft, a watercraft, a spacecraft, a video game console, an arcade video game unit, a smartphone, an entertainment device, an appliance, a laptop computer, a desktop computer, a tablet, a notebook, or any other suitable type of electronic device or system.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

In this description, unless otherwise stated, “about,” “approximately” or “substantially” preceding a parameter means being within +/−10 percent of that parameter. Modifications are possible in the described examples, and other examples are possible within the scope of the claims.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device, or a semiconductor component.

What is claimed is:

1. A semiconductor package, comprising:
a substrate including a build-up film isolation layer and first and second pre-preg layers contacting opposing lateral sides of the build-up film isolation layer, the first pre-preg layer including a first metallization, the second pre-preg layer including a second metallization not in physical contact with the first metallization;
solder mask layers on top and bottom surfaces of the substrate;
a first semiconductor die coupled to the first metallization;
a second semiconductor die coupled to the second metallization, the first and second semiconductor dies configured to operate in separate voltage domains; and
a mold compound covering the substrate and the first and second semiconductor dies.

2. The semiconductor package of claim 1, wherein a minimum lateral distance between a third metallization in the build-up film isolation layer and an interface between the build-up film isolation layer with the second pre-preg layer is at least 100 microns.

3. The semiconductor package of claim 1, wherein the build-up film isolation layer includes first and second coils not in physical contact with each other, the first coil coupled to the first semiconductor die and the second coil coupled to the second semiconductor die.

4. The semiconductor package of claim 1, wherein the build-up film isolation layer includes an epoxy-based resin, an inorganic filler, and a curing agent and does not include fiberglass.

5. The semiconductor package of claim 1, wherein the build-up film isolation layer has a dielectric constant between 3.2 and 3.4 at 5.8 GHz.

6. The semiconductor package of claim 1, wherein the build-up film isolation layer has a coefficient of thermal expansion (CTE) ranging from 20 parts per million per degree Kelvin (ppm/K) to 39 ppm/K.

7. The semiconductor package of claim 1, wherein the first pre-preg layer is 36%-77% fiberglass by weight.

8. A semiconductor package, comprising:
a substrate including first metallization, second metallization, a first coil, and a second coil, the first metallization and the first coil in a first voltage domain and the second metallization and the second coil in a second voltage domain, the first metallization covered by a first pre-preg layer, the second metallization covered by a second pre-preg layer, and the first and second coils covered by a build-up film isolation layer;
a first solder mask layer contacting top surfaces of the first and second pre-preg layers and of the build-up film isolation layer;
a second solder mask layer contacting bottom surfaces of the first and second pre-preg layers and of the build-up film isolation layer;
a first semiconductor die coupled to the first metallization and the first coil;
a second semiconductor die coupled to the second metallization and the second coil; and
a mold compound contacting the first and second semiconductor dies and the first solder mask.

9. The semiconductor package of claim 8, wherein a minimum lateral distance between the first coil in the build-up film isolation layer and an interface between the build-up film isolation layer with the second pre-preg layer is at least 100 microns.

10. The semiconductor package of claim 8, wherein the build-up film isolation layer includes an epoxy-based resin, an inorganic filler, and a curing agent and does not include fiberglass.

11. The semiconductor package of claim 8, wherein the build-up film isolation layer has a dielectric constant between 3.2 and 3.4 at 5.8 GHz.

12. The semiconductor package of claim 8, wherein the first pre-preg layer is 36%-77% fiberglass by weight.

13. The semiconductor package of claim 8, wherein the build-up film isolation layer has a coefficient of thermal expansion (CTE) ranging from 20 parts per million per degree Kelvin (ppm/K) to 39 ppm/K.

14. A method for manufacturing a semiconductor package, comprising:
forming two or more layers of a substrate by iteratively:
plating a metal layer;
applying a build-up film to the metal layer using a first mask;
applying a first pre-preg to the metal layer on a first lateral side of the build-up film; and
applying a second pre-preg to the metal layer on a second lateral side of the build-up film, the second lateral side opposing the first lateral side; and
applying a solder mask layer to the substrate;
coupling first and second semiconductor dies to the substrate, the first and second semiconductor dies configured to operate in separate voltage domains; and
covering the substrate and the first and second semiconductor dies with a mold compound.

15. The method of claim 14, wherein the forming of the two or more layers of the substrate includes forming a pre-preg layer and a build-up film isolation layer including a coil, and wherein a minimum lateral distance between the coil and an interface between the build-up film isolation layer and the pre-preg layer is at least 100 microns.

16. The method of claim 15, wherein the forming of the two or more layers of the substrate includes forming the build-up film isolation layer including a second coil, wherein the coil and the second coil are not in physical contact with each other, the coil coupled to the first semiconductor die and the second coil coupled to the second semiconductor die.

17. The method of claim 15, wherein the build-up film isolation layer includes an epoxy-based resin, an inorganic filler, and a curing agent and does not include fiberglass.

18. The method of claim 15, wherein the build-up film isolation layer has a dielectric constant between 3.2 and 3.4 at 5.8 GHz.

19. The method of claim 15, wherein the pre-preg layer is 36%-77% fiberglass by weight.

20. The method of claim 15, wherein the build-up film isolation layer has a coefficient of thermal expansion (CTE) ranging from 20 parts per million per degree Kelvin (ppm/K) to 39 ppm/K.
